(19) United States
(12) Patent Application Publication
(10) Pub. No.: US 2012/0199922 A1
(43) Pub. Date: Aug. 9, 2012

(54) STORAGE ELEMENT AND MEMORY DEVICE

(75) Inventors: Hiroyuki Uchida, Kanagawa (JP); Masanori Hosomi, Tokyo (JP); Hiroyuki Oomori, Kanagawa (JP); Kazuhiro Bessho, Kanagawa (JP); Yutaka Higo, Kanagawa (JP); Tetsuya Asayama, Tokyo (JP); Kazutaka Yamane, Kanagawa (JP)

(73) Assignee: SONY CORPORATION, Tokyo (JP)

(21) Appl. No.: 13/358,016

(22) Filed: Jan. 25, 2012

(30) Foreign Application Priority Data
Feb. 3, 2011 (JP) 2011-021342

(51) Int. Cl. H01L 29/82

(52) U.S. Cl. 257/421; 257/E29.323

(57) ABSTRACT

A storage element includes: a storage layer that has magnetization perpendicular to a film face, the direction of the magnetization being changed corresponding to information; a magnetization fixed layer that has magnetization perpendicular to a film face that is a reference of the information stored in the storage layer; and an insulating layer that is formed of a nonmagnetic body provided between the storage layer and the magnetization fixed layer. The magnetization fixed layer has a structure in which the nonmagnetic layer is interposed between upper and lower ferromagnetic layers which have a laminated ferri-pinned structure of magnetically anti-parallel coupling. The direction of the magnetization of the storage layer is changed by injecting spin-polarized electrons in a lamination direction of a layer structure having the storage layer, the insulating layer, and the magnetization fixed layer, and recording of the information is performed on the storage layer.

### BACKGROUND

The present disclosure relates to a storage element having a storage layer that stores a magnetization state of a ferromagnetic layer as information and a magnetization fixed layer in which the direction of magnetization is fixed, to change the direction of magnetization of the storage layer by causing electric current to flow, and a memory device provided with the storage element.

In an information apparatus such as a computer, a DRAM with a high speed operation and high density has been widely used as a Random Access Memory.

However, the DRAM is a volatile memory from which the information therein disappears when the power is turned off, and a nonvolatile memory from which information does not disappear is preferable.

A Magnetic Random Access Memory (MRAM) recording information by magnetization of a magnetic body has garnered attention as a candidate for the nonvolatile memory, and development thereof is progressing.

The MRAM performs recording of information in such a manner that electric current is caused to flow in two kinds of substantially perpendicular address lines (word line and bit line) and magnetization of a magnetic layer of a magnetic storage element at an intersection of the address lines is inverted by a current magnetic field generated from each address line.

A schematic view (perspective view) of a general MRAM is shown in FIG. 13.

A drain area 108, a source area 107, and a gate electrode 101 constituting a selection transistor for selecting each memory cell are formed at parts isolated by an element isolating layer 102 of a semiconductor substrate 110 such as a silicon substrate.

A word line 105 extending in the forward and backward directions in the figure is provided above the gate electrode 101.

The drain area 108 is formed commonly to the left and right selection transistors in the figure, and a line 109 is connected to the drain area 108.

A magnetic storage element 103 having a storage layer in which the direction of magnetization is reversed is provided between the word line 105 and a bit line 106 extending in the left and right directions in the figure provided above. The magnetic storage element 103 is configured by, for example, a magnetic tunnel junction element (MTJ element).

The magnetic storage element 103 is electrically connected to the source area 107 through a bypass line 111 in the horizontal direction and a contact layer 104 in the up and down directions.

Electric current is caused to flow in the word line 105 and the bit line 106 to apply current magnetic field to the magnetic storage element 103, thus the direction of magnetization of the storage layer of the magnetic storage element 103 is reversed, and it is possible to perform recording of information.

In a magnetic memory such as MRAM, to stably keep the recorded information, it is necessary that a magnetic layer (storage layer) recording the information has regular coercive force.

To rewrite the recorded information, electric current to the extent of that of the address line has to be allowed to flow.

However, the address line gets thinner according to miniaturization of the element constituting the MRAM, and thus it is difficult to cause sufficient electric current to flow.

As a configuration in which the magnetization can be reversed with less electric current, a memory having a configuration using the magnetization inversion by spin injection (for example, Japanese Unexamined Patent Application Publication No. 2003-17782, Specification of U.S. Pat. No. 6,256,223, Japanese Unexamined Patent Application Publication No. 2008-227388, PHYs. Rev. B, 54.9353 (1996), and J. Magn. Mat., 159, L1 (1996)) has been garnering attention.

The magnetization inversion based on the spin injection means that spin-polarized electrons passing through a magnetic body are injected into the other magnetic body to cause the magnetization inversion for the other magnetic body.

For example, in a giant magnetoresistance effect element (GMR element) or a magnetic tunnel junction element (MTJ element), electric current is caused to flow in a direction perpendicular to a film face, and thus it is possible to reverse the direction of magnetization of at least a part of the magnetic layer of such an element.

The magnetization inversion based on the spin injection has an advantage that it is possible to realize the magnetization inversion without increasing electric current even when the element is miniaturized.

A schematic view of a memory device having a configuration using the magnetization inversion based on the spin injection is shown in FIG. 14 and FIG. 15. FIG. 14 is a perspective view and FIG. 15 is a cross-sectional view.

A drain area 58, a source area 57, and a gate electrode 51 constituting a selection transistor for selecting each memory cell are formed at parts isolated by an element isolating layer 52 of a semiconductor substrate 60 such as a silicon substrate. Among them, the gate electrode 51 also serves as the word line extending in the forward and backward directions of FIG. 14.

The drain area 58 is commonly formed at the left and right selection transistors of FIG. 14, and a line 59 is connected to the drain area 58.

A storage element 53 having a storage layer in which the direction of magnetization is reversed by spin injection is provided between the source area 57 and the bit line 56 provided above and extending in the left and right directions of FIG. 14.

The storage element 53 is configured by, for example, a magnetic tunnel junction element (MTJ element). The storage element 53 has two magnetic layers 61 and 62. Between two-layer magnetic layers 61 and 62, one magnetic layer is a magnetization fixed layer in which the direction of magnetization is fixed, and the other magnetic layer is a magnetization free layer in which the direction of magnetization is changed, that is, a storage layer.

The storage element 53 is connected to the bit line 56 and the source area 57 through up and down contact layers 54. Accordingly, electric current is caused to flow in the storage element 53, and thus it is possible to reverse the direction of magnetization of the storage layer by spin injection.

In a case of the memory device having the configuration using the magnetization inversion based on the spin injection, it is possible to simplify a device structure as compared with the general MRAM shown in FIG. 13, and thus it is possible to achieve increased density.

By using the magnetization inversion based on the spin injection, there is an advantage that electric current of writing is not increased even when the miniaturization of the element proceeds as compared with the general MRAM performing the magnetization inversion by external magnetic field.

### SUMMARY

In the case of the MRAM, a writing line (word line or bit line) is provided separately from the storage element, and writing (recording) of information is performed by current magnetic field generated by causing electric current to flow in the writing line. For this reason, it is possible to cause the amount of electric current necessary for writing to sufficiently flow.

Meanwhile, in the memory device having the configuration using the magnetization inversion based on the spin injection, it is necessary to perform the spin injection by the electric current flowing in the storage device to reverse the direction of magnetization of the storage layer.

Since the storage element performs writing (recording) of the information by causing the electric current to directly flow in the storage element, the memory cell is configured by connecting the storage element to the selection transistor to select the memory cell performing the writing. In this case, the electric current flowing in the storage element is limited to the magnitude of electric current (saturation electric current of selection transistor) capable of flowing in the selection transistor.

For this reason, it is necessary to perform the writing with less electric current than the saturation electric current of the selection transistor, and it is possible to reduce the electric current flowing in the storage element by improving the efficiency of the spin injection.

To enlarge a reading signal, it is necessary to secure a high magnetic resistance change rate. For this reason, a configuration of a storage element in which an intermediate layer coming in contact with both sides of the storage layer is a tunnel insulating layer (tunnel barrier layer) is effective.

When the tunnel insulating layer is used as the intermediate layer as described above, there is a limit to the amount of electric current flowing in the storage element to prevent the insulation of the tunnel insulating layer from being broken. From this viewpoint, it is necessary to suppress the electric current at the time of the spin injection.

To decrease the current value, since the current value is in proportion to a film thickness of the storage layer and is in proportion to the square of the saturation magnetization of the storage layer, it is preferable to adjust them (film thickness and saturation magnetization) (for example, F. J. Albert et al., Appl. Phy. Lett., 77, 3809 (2000)).

For example, in U.S. Patent Application Publication No. 2005/0184839 A1, it is described that it is possible to reduce the current value when the magnetization amount (Ms) of the recording material is reduced.

However, when the information written by electric current is not stored, a nonvolatile memory is not obtained. That is, it is necessary to secure stability with respect to thermal fluctuation (thermal stability) of the storage layer.

In a case of the storage element using the magnetization inversion based on the spin injection, the volume of the storage layer is decreased as compared with the MRAM of the related art. Simply, the thermal stability tends to decrease.

When the thermal stability of the storage layer is not secured, the reversed direction of magnetization is reversed again due to heat and becomes a writing error.

When capacity increases of the storage element proceed using the magnetization inversion based on the spin injection, the volume of the storage element is further decreased, and thus the securing of the thermal stability is an important problem.

For this reason, in the storage element using the magnetization inversion based on the spin injection, the thermal stability is a very important characteristic.

Accordingly, it is necessary to reduce the electric current necessary for the magnetization inversion based on the spin injection equal to or less than the saturation electric current of the transistor and to secure the thermal stability for reliably keeping the written information such that the storage element having the configuration of reversing the direction of magnetization of the storage layer by the spin injection can be present as the memory.

As described above, to reduce the electric current necessary for the magnetization inversion based on the spin injection, it is conceivable that the saturation magnetization amount Ms of the storage layer is reduced or the storage layer is made thin. For example, as described in U.S. Patent application Publication No. 2005/0184839 A1, it is effective to use a material with a low saturation magnetization amount Ms as a material of the storage layer. However, as described above, simply, when the material with the low saturation magnetization amount Ms is used, it is difficult to secure the thermal stability for reliably keeping the information.

In the present disclosure, it is desirable to provide a storage element capable of improving thermal stability without increasing writing electric current, and a memory device having the storage element. In addition, in the present disclosure, it is desirable to provide a storage element having excellent characteristics even when a magnetic material constituting a storage layer is subjected to heat treatment of 350° C. or higher.

According to an embodiment of the present disclosure, there is provided a storage element including: a storage layer that has magnetization perpendicular to a film face, the direction of the magnetization being changed corresponding to information; a magnetization fixed layer that has magnetization perpendicular to a film face that is a reference of the information stored in the storage layer; and an insulating layer that is formed of a nonmagnetic body provided between the storage layer and the magnetization fixed layer, wherein the magnetization fixed layer has a structure in which the nonmagnetic layer is interposed between upper and lower ferromagnetic layers, and the upper and lower ferromagnetic layers have a laminated ferri-pinned structure of magnetically anti-parallel coupling, wherein the direction of the magnetization of the storage layer is changed by injecting spin-polarized electrons in a lamination direction of a layer structure having the storage layer, the insulating layer, and the magnetization fixed layer, and recording of the information is performed on the storage layer, and wherein the magnitude of effective diamagnetic field received by the storage layer is less than a saturation magnetization amount of the storage layer.

In the storage element, a plurality of structures may be formed in which the nonmagnetic layer is interposed between the upper and lower ferromagnetic layers.

In the storage element, a ferromagnetic material constituting an interface of the storage layer and the insulating layer may be Co—Fe—B.

In the storage element, a composition of Co—Fe—B may be (Coₓ—Fe_{y})_{100-z}—B_{z}, where 0≦Coₓ≦40, 60≦Fe_{y}≦100, and 0<B_{z}≦30.

In the storage element, a composition of Co—Fe—B may be (Coₓ—Fe_{y})_{100-z}—B_{z}, where 0≦Coₓ≦40, 60≦Fe_{y}≦100, and 20<B_{z}≦40.

In the storage element, a material of the ferromagnetic layer constituting the magnetization fixed layer may be Co—Fe—B, and a composition thereof may be (Coₓ—Fe_{y})_{100-z} —B_{z}, where 0≦Coₓ≦40, 60≦Fe_{y}≦100, and 0<b_{z}≦30, or may be (Coₓ—Fe_{y})_{100-z} —B_{z}, where 0≦Coₓ≦40, 60≦Fe_{y}≦100, and 20<B_{z}≦40.

In the storage element, the nonmagnetic layer on the insulating layer side of the magnetization fixed layer may be Ta.

According to another embodiment of the present disclosure, there is provided a memory device including: a storage element that stores information by a magnetization state of a magnetic body; and two kinds of lines that intersect with each other, the storage element has the configuration of the storage element of the embodiment of the present disclosure, the storage element is provided between the two kinds of lines, and electric current in the lamination direction flows in the storage element through the two kinds of lines, and the spin-polarized electrons are injected.

According to the configuration of the storage element of the embodiment of the present disclosure, the storage layer that stores information by the magnetization state of the magnetic body is provided, the magnetization fixed layer is provided for the storage layer through the intermediate layer, the intermediate layer is formed of an insulator, the direction of magnetization of the storage layer is changed by injecting the spin-polarized electrons in the lamination direction, the recording of the information is performed on the storage layer, and thus it is possible to perform the recording of the information by injecting the spin-polarized electrons by causing electric current to flow in the lamination direction.

The magnitude of the effective diamagnetic field received by the storage layer is less than the saturation magnetization amount of the storage layer, the diamagnetic field received by the storage layer becomes low, and thus it is possible to reduce the amount of writing electric current necessary to reverse the direction of magnetization of the storage layer.

Meanwhile, since it is possible to reduce the amount of writing electric current even when the saturation magnetization amount of the storage layer is not reduced, it is possible to sufficiently secure thermal stability of the storage layer in which the saturation magnetization amount of the storage layer is a sufficient amount.

Particularly, in the storage element of the embodiment of the present disclosure, the storage layer and the magnetization fixed layer have magnetization perpendicular to the film face. Having vertical magnetic anisotropy is more suitable for low power consumption and high capacity than having in-plane magnetic anisotropy. The reason is because the energy barrier which the perpendicular magnetization has to be over at the time of spin torque magnetization inversion is low, and the thermal stability of the information storage of the storage layer is advantageous due to the high magnetic anisotropy of the perpendicular magnetization film.

According to the configuration of the memory device of the embodiment of the present disclosure described above, the storage element is provided between the two kinds of lines, and the electric current in the lamination direction flows in the storage element through the two kinds of lines, and the spin-polarized electrons are injected. Accordingly, it is possible to perform the recording of information by the spin injection by causing the electric current to flow in the lamination direction of the storage element through the two kinds of lines.

Since it is possible to reduce the amount of writing electric current of the storage element even when the saturation magnetization amount of the storage layer is not reduced, it is possible to stably store the information recorded in the storage element and to reduce the power consumption of the memory device.

According to the present disclosure, since it is possible to reduce the amount of writing electric current of the storage element even when the saturation magnetization amount of the storage layer is not reduced, it is possible to sufficiently secure the thermal stability that is information storage capability and to configure the storage element with excellent characteristic balance. With such a configuration, an operation error is removed, and thus it is possible to sufficiently obtain an operation margin of the storage element.

Particularly, the ferromagnetic material constituting the storage layer is Co—Fe—B, the composition of Co—Fe—B is (Coₓ—Fe_{y})_{100-z} —B_{z}, where 0≦Coₓ≦40, 60≦Fe_{y}≦100, and 0<B_{z}≦30, and it is very suitable to form the storage layer of the perpendicular magnetization.

Considering that a heat treatment temperature is a relatively high temperature such as about 350° C. to 450° C., when the composition of Co—Fe—B is (Coₓ—Fe_{y})_{100-z} —B_{z} where 0≦Coₓ≦40, 60≦Fe_{y}≦100, and 20<B_{z}≦40, the ferromagnetic layer material constituting the storage layer exhibits a high tunnel magnetoresistance effect even in the high temperature heat treatment, and thus it is very suitable.

Since the magnetization fixed layer is a laminated ferri-pinned structure, it is possible to strengthen the vertical magnetic anisotropy of the magnetization fixed layer and to raise the thermal stability of the storage element.

The material of the ferromagnetic layer of the magnetization fixed layer is Co—Fe—B that is the same as that of the storage layer, the composition of Co—Fe—B is (Coₓ—Fe_{y})_{100-z} —B_{z}, where 0≦Coₓ≦40, 60≦Fe_{y}≦100, and 0<B_{z}≦30, and it is very suitable to form the magnetization fixed layer of the perpendicular magnetization.

Considering that a heat treatment temperature is a relatively high temperature such as about 350° C. to 450° C., when the composition of Co—Fe—B is (Coₓ—Fe_{y})_{100-z} —B_{z}, where 0≦Coₓ≦40, 60≦Fe_{y}≦100, and 20<B_{z}≦40, and it is very suitable to form the magnetization fixed layer of the perpendicular magnetization.

Accordingly, it is possible to realize a memory device with high reliability, which stably operates.

The writing electric current is reduced, and thus it is possible to reduce the power consumption when the writing is performed on the storage element.

Therefore, it is possible to reduce the power consumption of the whole memory device.

### BRIEF DESCRIPTION OF THE DRAWINGS

FIG. 1 is a diagram illustrating a schematic configuration of a memory device according to an embodiment of the present disclosure.

FIG. 2 is a cross-sectional view illustrating a storage element of the embodiment.

FIG. 3 is a diagram illustrating a layer structure of a sample of a storage element used in a test.

FIG. 4 is a diagram illustrating a relationship between the content of Co of the storage layer of a size of 0.09×0.18 μm and inversion current density.

FIG. 5 is a diagram illustrating a relationship between the content of Co of the storage layer of a size of 0.09×0.18 μm and an indicator of thermal stability.

FIG. 6 is a diagram illustrating a relationship between the content of Co of the storage layer of a size of 50 nmφ and an indicator of thermal stability.

FIG. 7 is a diagram illustrating a layer structure of a sample of a storage element used in a test.

FIG. 8 is a diagram illustrating heat treatment temperature dependency of TMR for each composition of Co—Fe—B of the storage layer of the embodiment.

FIG. 9A, FIG. 9B, and FIG. 9C are diagrams illustrating a measurement result of TMR characteristics when a B density and a heat treatment temperature are changed at a ratio of Co/Fe in Co—Fe—B of the storage layer of the embodiment.

FIG. 10 is a diagram illustrating a layer structure of a sample of the storage element used in a test.

FIG. 11A and FIG. 11B are diagrams illustrating a test result of change in characteristics in a relationship between a difference of a laminated ferri-pinned structure of a magnetization fixed layer in the embodiment and a heat treatment based on a difference in temperature at the step of producing the storage element.

FIG. 12A, FIG. 12B, and FIG. 12C are diagrams illustrating a test result of change in characteristics based on a difference in thickness of a nonmagnetic layer in the laminated ferri-pinned structure of the magnetization fixed layer in the embodiment.

FIG. 13 is a perspective view schematically illustrating a configuration of an MRAM of the related art.

FIG. 14 is a diagram illustrating a schematic configuration of a memory device using magnetization inversion based on spin injection.

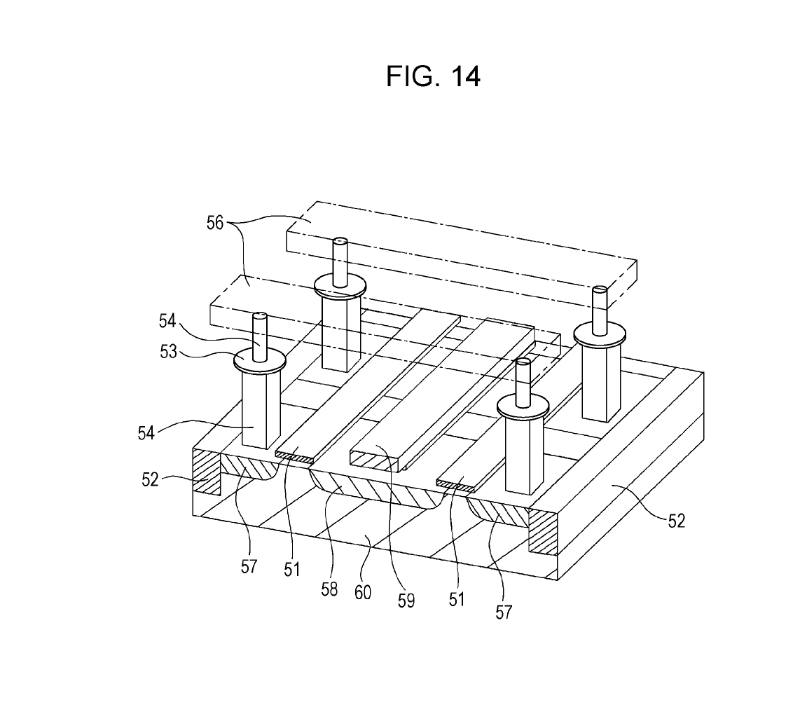

FIG. 15 is a cross-sectional view of the memory device shown in FIG. 14.

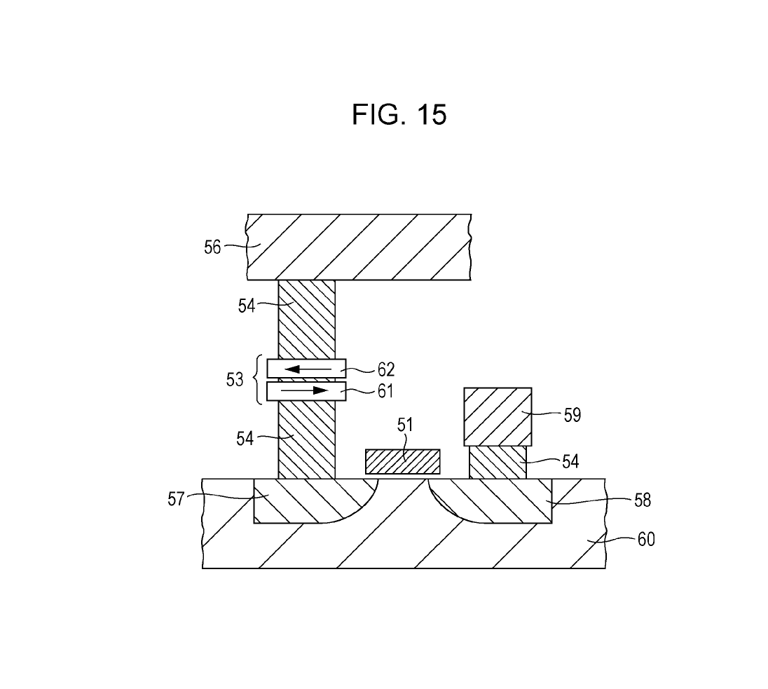

### DETAILED DESCRIPTION OF EMBODIMENTS

Hereinafter, embodiments of the present disclosure will be described in the following order.

<1. Outline of Storage Element of Embodiment>

<2. Specific Configuration 1 of Storage Layer and Magnetization Fixed Layer of Embodiment>

<3. Specific Configuration 2 of Storage Layer and Magnetization Fixed Layer of Embodiment>

<4. Laminated Ferri-pinned Structure of Magnetization Fixed Layer of Embodiment>

<5. Test about Embodiments>

<6. Modified Example>

### 1. Outline of Storage Element of Embodiment

First, an outline of a storage element according to an embodiment of the present disclosure will be described.

In the embodiment of the present disclosure, the direction of magnetization of a storage layer of a storage element is reversed by the spin injection described above, to perform recording of information.

The storage layer is configured by a magnetic body such as a ferromagnetic layer, and stores information by a magnetization state (direction of magnetization) of the magnetic body.

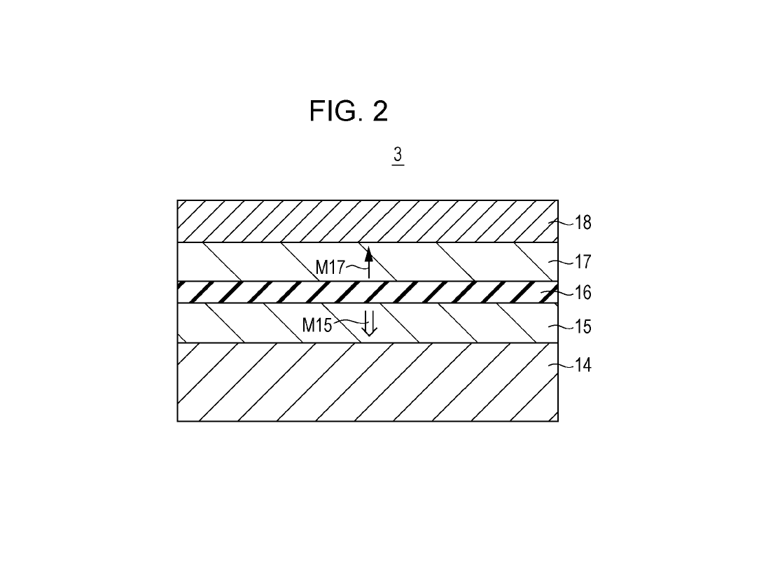

Although described in detail later, the storage element has a layer structure shown in FIG. 2 as an example, is provided with a storage layer 17 and a magnetization fixed layer 15 as at least two magnetic layers, and is provided with an insulating layer 16 (tunnel insulating layer) as an intermediate layer interposed between two magnetic layers.

The storage layer 17 has magnetization perpendicular to a film face, and the direction of magnetization is changed corresponding to information.

The magnetization fixed layer 15 has magnetization perpendicular to a film face that is reference of the information stored in the storage layer 17.

The insulating layer 16 is a nonmagnetic body, and is provided between the storage layer 17 and the magnetization fixed layer 15.

By injecting spin-polarized electrons in a lamination direction of the layer structure having the storage layer 17, the insulating layer 16, and the magnetization fixed layer 15, the direction of magnetization of the storage layer 17 is changed to perform the recording of information on the storage layer 17.

A basic operation of reversing the direction of magnetization of the magnetic layer (storage layer 17) by the spin injection is to cause electric current equal to or larger than a predetermined threshold value to flow in a direction perpendicular to the film face with respect to the storage element formed of a giant magnetoresistance effect element (GMR element) or a tunnel magnetoresistance effect element (MTJ element). In this case, the polarity (direction) of electric current depends on the reversed direction of magnetization.

When electric current with an absolute value smaller than the threshold value is caused to flow, the magnetization inversion does not occur.

When the direction of magnetization of the magnetic layer is reversed by the spin injection, a threshold value Ic of necessary electric current is generally represented by Ic=A·α·Ms·V·Hd/2η.

Herein, A is a constant, α is a spin damping constant, η is a spin injection efficiency, Ms is a saturation magnetization amount, V is a volume of a storage layer, and Hd is an effective diamagnetic field.

As shown in the formula, the threshold value of electric current may be arbitrarily set by controlling the volume V of the magnetic layer, the saturation magnetization Ms of the magnetic layer, the spin injection efficiency 11, and the spin damping constant α.

More strictly, when the direction of magnetization of the magnetic layer is reversed by spin torque magnetization inversion, the threshold value Ic of necessary electric current is different according to whether an axis of easy magnetization of the magnetic layer is an in-plane direction or a vertical direction.

The storage element of the embodiment is a perpendicular magnetization type. However, when the inversion electric current of reversing the direction of magnetization of the magnetic layer in a case of the in-plane magnetization type storage element of the related art is Ic_para, and when the direction is reversed from the same direction to the reverse direction (the same direction and the reverse direction are magnetization directions of the storage layer in which the magnetization direction of the magnetization fixed layer is reference, the same direction may be represented by “parallel”, and the reverse direction may be represented by “anti-parallel”),

Ic_para=(A·α·Ms·V/g(0)/P)(Hk+2πMs).

When the direction is reversed from the reverse direction to the same direction,

Ic_para=−(A·α·Ms·V/g(π)/P)(Hk+2πMs).

Meanwhile, when the inversion electric current of the perpendicular magnetization type storage element of the example is Ic_perp and the direction is reversed from the same direction to the reverse direction,

Ic_perp=(A·α·Ms·V/g(0)/P)(Hk−4πMs).

When the direction is reversed from the reverse direction to the same direction,

Ic_perp=−(A·α·Ms·V/g(π)/P)(Hk−4πMs).

However, A is a constant, α is a damping constant, Ms is saturation magnetization, V is an element volume, P is a spin polarization rate, g(0) and g(π) are a coefficient corresponding to the efficiency in which the spin torque is transmitted to the opponent magnetic layer at the time of the same direction and at the time of the reverse direction, respectively, and Hk is a magnetic anisotropy (see Nature Materials., 5, 210 (2006)).

In each formula, when the case of perpendicular magnetization type (Hk−4πMs) is compared with the case of the in-plane magnetization type (Hk+2πMs), it can be understood that the perpendicular magnetization type is suitable to lowering the recording electric current.

The storage element of the example performs reading of information by difference of resistance caused by the tunnel magnetoresistance effect. That is, when the tunnel magnetoresistance effect is large, the output becomes large. The tunnel magnetoresistance effect TMR is represented by the formula (1) using the spin polarization rate: P.

$$T M R ( \% ) = \frac{{P}_{1} {P}_{2}}{1 - {P}_{1} {P}_{2}} \times 100 \qquad ( 1 )$$

Herein, P1 is a spin polarization rate of the magnetization fixed layer, and P2 is a spin polarization rate of the recording layer. In the formula (1), it can be understood that the TMR becomes large when the spin polarization rate is large.

It indicates that the low electric current and the high output (=high TRM) are in a coexistence relationship by the comparison of the formula of the reverse electric current.

In the embodiment, the storage element having the magnetic layer (storage layer 17) capable of storing the information by the magnetization state, and the magnetization fixed layer 15 in which the direction of magnetization is fixed, is configured.

To exist as a memory, the written information should be able to be stored. As an indicator of capability of storing information, determination is performed by a value of an indicator Δ of the thermal stability (=KV/k_{B}T). The Δ is represented by the following formula (2).

Δ=KV/k_{B}T=Ms·V·H_{K}·(½k_{B}T) (2)

Herein, Hk is effective anisotropy magnetic field, k_{B} is a Boltzmann constant, T is a temperature, Ms is a saturation magnetization amount, and V is a volume of a storage layer.

The effective anisotropy Hk receives an influence of a shape magnetic anisotropy, an induced magnetic anisotropy, a crystal magnetic anisotropy, and the like. When a single-domain coherent rotation model is assumed, it is equivalent to coercive force.

There are many cases where the indicator Δ of the thermal stability and the threshold value Ic of electric current are in a trade-off relationship. For this reason, to keep the memory characteristics, there are many cases where such coexistence is a problem.

In the threshold value of electric current of changing the magnetization state of the storage layer 17, in actual, for example, in an TMR element in which a thickness of the storage layer 17 is 2 nm and a planar pattern is substantially an oval type of 100 nm×150 nm, +side threshold value+Ic=+0.5 mA, and −side threshold value−Ic=−0.3 mA, and a current density in that case is about 3.5×10⁶ A/cm². They substantially match the formula of Ic.

In the general MRAM in which the magnetization inversion is performed by current magnetic field, a writing electric current of several mA or more is necessary.

Accordingly, when the magnetization inversion is performed by the spin injection, the threshold value of the writing electric current becomes sufficiently small as described above, and thus it is effective to reduce the power consumption of an integrated circuit.

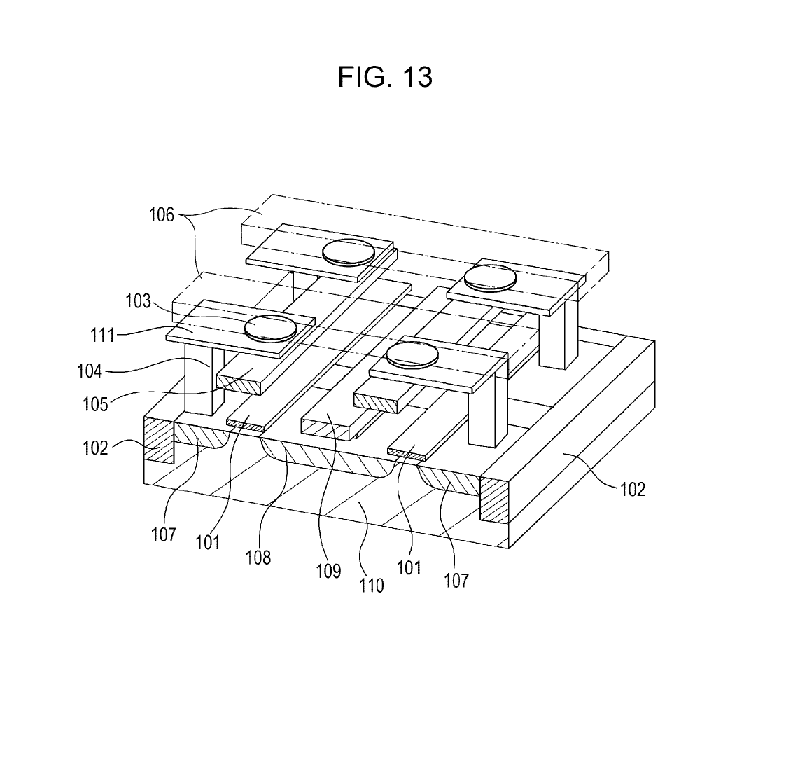

Since the line (line 105 shown in FIG. 13) for generating current magnetic field necessary for the general MRAM is not necessary, an integration degree is advantageous as compared with the general MRAM.

When the magnetization inversion is performed by the spin injection, the electric current is caused to directly flow in the storage element to write (record) information. Accordingly, to select a memory cell performing the writing, the storage element is connected to the selection transistor to configure the memory cell.

In this case, the electric current flowing in the storage element is limited by the magnitude of the electric current (saturation electric current of selection transistor) capable of flowing in the selection transistor.

To decrease the threshold value Ic of the electric current of the magnetization inversion based on the spin injection to be smaller than the saturation electric current of the selection transistor, it is preferable to reduce the saturation magnetization amount Ms of the storage layer 17 from the formula of Ic.

However, when the saturation magnetization amount Ms is simply reduced (for example, U.S. Patent Publication No. 2005/0184839 A1), the thermal stability of the storage layer 17 is significantly damaged, and it is difficult to accomplish the function as a memory.

To configure the memory, it is necessary that the indicator Δ of the thermal stability have magnitude equal to or larger than some extent.

The inventors of the present disclosure have conducted a variety of research into this. As a result, for example, it was found that a composition of Co—Fe—B is selected as a ferromagnetic layer constituting the storage layer 17, and the magnitude of effective diamagnetic field (Meffective) received by the storage layer 17 becomes smaller than the saturation magnetization amount Ms of the storage layer 17.

By using the ferromagnetic material described above, the magnitude of the effective diamagnetic field received by the storage layer 17 is smaller than the saturation magnetization amount Ms of the storage layer 17.

Accordingly, since the diamagnetic field received by the storage layer 17 can be decreased, it is possible to obtain the effect of reducing the threshold value Ic of the electric current represented by the formula of the Ic without damaging the thermal stability Δ represented by the formula (2).

The inventors found that Co—Fe—B is magnetized in the film-face perpendicular direction in the limited composition range of the selected Co—Fe—B compositions, and thus it is possible to secure the sufficient thermal stability even in very small storage element capable of realizing Gbit-class capacity.

Accordingly, in the state of keeping the thermal stability in the spin injection type magnetization inversion memory of Gbit class, it is possible to form a stable memory capable of writing information with low electric current.

In the embodiment, it is configured that the magnitude of the effective diamagnetic field received by the storage layer 17 is smaller than the saturation magnetization amount Ms of the storage layer 17, that is, the value of a ratio of the magnitude of effective diamagnetic field to the saturation magnetization amount Ms of the storage layer 17 is smaller than 1.

Considering the saturation current value of the selection transistor, a magnetic tunnel junction (MTJ) element is configured using a tunnel insulating layer (insulating layer 16) formed of an insulator as a nonmagnetic intermediate layer between the storage layer 17 and the magnetization fixed layer 15.

The reason is because it is possible to raise the magnetoresistance change ratio (MR ratio) as compared with the case of configuring the giant magnetoresistance effect (GMR) element using a nonmagnetic conductive layer by configuring the magnetic tunnel junction (MTJ) element using the tunnel insulating layer, and thus it is possible to enlarge the reading signal strength.

Particularly, magnesium oxide (MgO) is used as a material of the tunnel insulating layer 16, and thus it is possible to raise the magnetoresistance change ratio (MR ratio) as compared with the case of using aluminum oxide which has been generally used hitherto.

Generally, the spin injection efficiency depends on the MR ratio, the spin injection efficiency improves as MR ratio increases, and thus it is possible to lower the magnetization inversion current density.

Accordingly, magnesium oxide is used as the material of the tunnel insulating layer 16 that is the intermediate layer, the storage layer 17 is used, it is possible to thereby decrease the writing threshold value electric current based on the spin injection, and thus it is possible to perform the writing (recording) of information with small electric current. In addition, it is possible to enlarge the reading signal strength.

Accordingly, it is possible to secure the MR ratio (TMR ratio) and to reduce the writing threshold value electric current based on the spin injection, and thus it is possible to perform the writing (recording) of information with small electric current. In addition, it is possible to enlarge the reading signal strength.

When the tunnel insulating layer 16 is formed by the magnesium oxide (MgO) film as described above, the MgO film is crystallized, and it is more preferable to keep a crystalline alignment property in a 001 direction.

In the embodiment, the intermediate layer (tunnel insulating layer 16) between the storage layer 17 and the magnetization fixed layer 15 may be configured using various insulators, dielectrics, and semiconductors such as aluminum oxide, aluminum nitride, SiO₂, Bi₂O₃, MgF₂, CaF, SrTiO₂, AlLaO₃, and Al—N—O, in addition to a configuration formed of magnesium oxide.

It is necessary to control an area resistance value of the tunnel insulating layer 16 to be equal to or less than several tens of Ωμm² from the viewpoint of obtaining the current density necessary to reverse the direction of magnetization of the storage layer 17 by the spin injection.

In the tunnel insulating layer 16 formed of the MgO film, it is necessary to set a film thickness of the MgO film to be equal to or smaller than 1.5 nm, such that the area resistance value falls within the range described above.

It is preferable to decrease the size of the storage element to easily reverse the direction of magnetization of the storage layer 17 with small electric current.

Accordingly, preferably, the area of the storage element is equal to or smaller than 0.01 μm².

The storage layer 17 of the embodiment may be formed by directly laminating different ferromagnetic layers with different compositions. A ferromagnetic layer and a soft magnetic layer may be laminated, or a plurality of ferromagnetic layers may be laminated through a soft magnetic layer or a nonmagnetic layer. Even when they are laminated as described above, it is possible to obtain the effect of the present disclosure.

Particularly, when the plurality of ferromagnetic layers are laminated through the nonmagnetic layer, it is possible to adjust the strength of interaction between layers of the ferromagnetic layers. Accordingly, it is possible to obtain the effect capable of suppressing the magnetization inversion current so as not to increase even when the dimension of the storage element is equal to or less than sub-micron. In this case, as the material of the nonmagnetic layer, Ru, Os, Re, Ir, Au, Ag, Cu, Al, Bi, Si, B, C, Cr, Ta, Pd, Pt, Zr, Hf, W, Mo, Nb, or alloy thereof may be used.

Preferably, the magnetization fixed layer 15 and the storage layer 17 have anisotropy in one direction.

Preferably, each film thickness of the magnetization fixed layer 15 and the storage layer 17 is 0.5 nm to 30 nm.

The other configuration of the storage element is the same as the configuration of the related art of the storage element in which information is recorded by the spin injection.

The magnetization fixed layer 15 may have a configuration in which the direction of magnetization is fixed, from only a ferromagnetic layer or by using antiferromagnetic coupling of an antiferromagnetic layer and a ferromagnetic layer.

The magnetization fixed layer 15 may have a configuration formed of a single-layer ferromagnetic layer or a laminated ferri-pinned structure in which a plurality of ferromagnetic layers are laminated through the nonmagnetic layer.

As a material of the ferromagnetic layer constituting the magnetization fixed layer 15 of the laminated ferri-pinned structure, Co, CoFe, CoFeB, and the like may be used. A material of the nonmagnetic layer, Ru, Re, Ir, Os, and the like may be used.

As a material of the antiferromagnetic layer, a magnetic body such as FeMn alloy, PtMn alloy, PtCrMn alloy, NiMn alloy, IrMn alloy, NiO, and Fe₂O₃ may be used.

By adding nonmagnetic elements such as Ag, Cu, Au, Al, Si, Bi, Ta, B, C, O, N, Pd, Pt, Zr, Hf, Ir, W, Mo, and Nb to such a magnetic body, magnetic characteristics may be adjusted or various kinds of properties of matter such as a crystal structure, a crystal property, and stability of matter.

The film configuration of the storage element has no problem even in the configuration in which the storage layer 17 is provided under the magnetization fixed layer 15 or above the magnetization fixed layer 15. In addition, there is no problem even in a so-called dual structure in which the magnetization fixed layer 15 is provided above and under the storage layer 17.

As a method of reading the information recorded in the storage layer 17 of the storage element, the storage layer 17 of the storage element is provided with a magnetic layer that is reference of information through a thin insulating film, the information may be read by ferromagnetic tunnel electric current flowing through the insulating layer 16, and may be read by the magnetoresistance effect.

### 2. Specific Configuration 1 of Storage Layer and Magnetization Fixed Layer of Embodiment

Subsequently, a specific configuration of the embodiment of the present disclosure will be described.

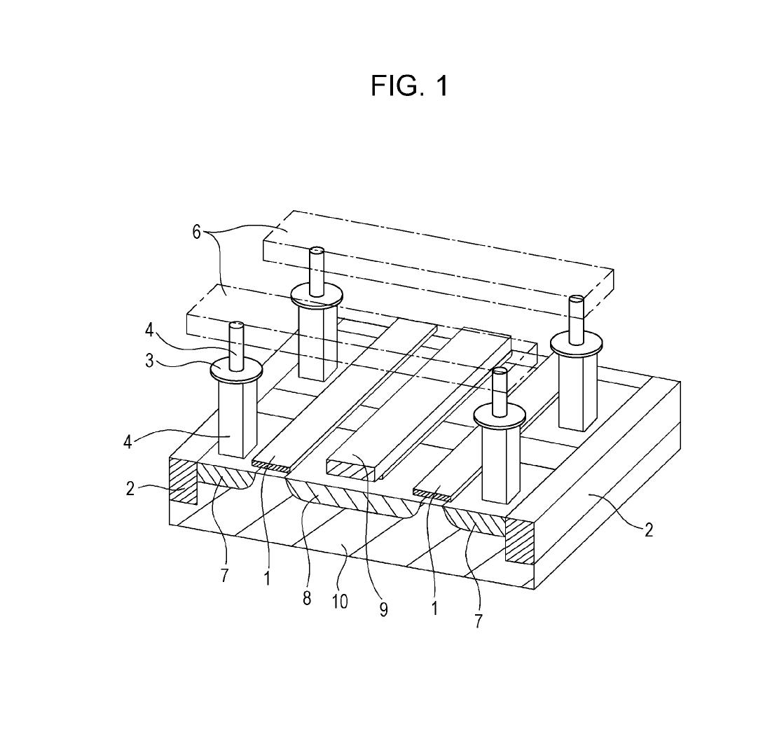

A schematic configuration view (perspective view) of the memory device as one specific configuration is shown in FIG. 1.

In the memory device, a storage element 3 capable of storing information in the magnetization state is provided in the vicinity of the intersection of two kinds of address lines (for example, word line and bit line) perpendicular to each other.

That is, a drain area 8, a source area 7, and a gate electrode 1 constituting a selection transistor for selecting each memory cell are formed at parts isolated by an element isolating layer 2 of a semiconductor substrate 10 such as a silicon substrate. The gate electrode 1 also serves as the address line (for example, word line) extending in forward and backward direction of the figure.

The drain area 8 is commonly formed in the left and right selection transistors of the figure, and the drain area 8 is connected to the line 9.

The storage element 3 is provided between the source area 7 and the other address line (for example, bit line) 6 provided on the upside and extending in the left and right directions. The storage element 3 has a storage layer formed of a ferromagnetic layer in which the direction of magnetization is reversed by the spin injection.

The storage element 3 is provided in the vicinity of the intersection of two kinds of address lines 1 and 6.

The storage element 3 is connected to the bit line 6 and the source area 7 through upper and lower contact layers 4.

Accordingly, the electric current is caused to flow in the up and down directions in the storage element 3 through two kinds of address lines 1 and 6, and thus it is possible to reverse the direction of magnetization of the storage layer by the spin injection.

A cross-sectional view of the storage element 3 of the memory device of the embodiment is shown in FIG. 2.

As shown in FIG. 2, the storage element 3 is formed by laminating a base layer 14, a magnetization fixed layer 15, an insulating layer 16, a storage layer 17, and a cap layer 18 in order from the lower layer side.

In this case, the storage layer 17 in which the direction of magnetization M17 is reversed by the spin injection is provided with the magnetization fixed layer 15 on the lower layer.

In the spin injection type magnetization inversion memory, “0” and “1” of information is regulated by a relative angle of the magnetization M17 of the storage layer 17 and the magnetization M15 of the magnetization fixed layer 15.

The insulating layer 16 which becomes a tunnel barrier layer (tunnel insulating layer) is provided between the storage layer 17 and the magnetization fixed layer 15, and the MTJ element is configured by the storage layer 17 and the magnetization fixed layer 15.

The base layer 14 is formed under the magnetization fixed layer 15, and the cap layer 18 is formed on the storage layer 17.

The storage layer 17 is configured from a ferromagnetic body having magnetic moment in which the direction of magnetization M17 is freely changed in the layer face perpendicular direction. The magnetization fixed layer 15 is configured from a ferromagnetic body having magnetic moment in which the magnetization M15 is fixed in the film face perpendicular direction.

The storage of information is performed by the direction of magnetization of the storage layer 17 having uniaxial anisotropy. The recording is performed by applying electric current in the film face perpendicular direction to cause spin torque magnetization inversion. As described above, in the storage layer 17 in which the direction of magnetization is reversed by the spin injection, the magnetization fixed layer 15 is provided on the lower layer thereof, and is considered as reference of the stored information (magnetization direction) of the storage layer 17.

In the embodiment, Co—Fe—B is used as the storage layer 17 and the magnetization fixed layer 15.

Particularly, the composition of Co—Fe—B is (Coₓ—Fe_{y})_{100-z}—B_{Z}, where 0≦Coₓ≦40, 60≦Fe_{y}≦100, and 0<B_{z}≦30.

The magnetization fixed layer 15 is the reference of information, and thus it is not preferable that the direction of magnetization is changed by recording or reading. However, it is not necessary that the direction is necessarily fixed in a specific direction. It is preferable that the coercive force is made larger than that of the storage layer 17, the film thickness is made thicker, or the magnetic damping constant is made larger so as not to more easily move than the storage layer 17.

When the magnetization is fixed, the magnetization fixed layer 15 may be indirectly fixed by bringing the antiferromagnetic body such as PtMn and IrMn in contact with the magnetization fixed layer 15 or magnetically coupling the magnetic body coming in contact with such an antiferromagnetic body through a nonmagnetic body such as Ru.

In the embodiment, particularly, the composition of the storage layer 17 of the storage element 3 is adjusted such that the magnitude of the effective diamagnetic field received by the storage layer 17 is smaller than the saturation magnetization amount Ms of the storage layer 17.

That is, as described above, the composition of the ferromagnetic material Co—Fe—B of the storage layer 17 is selected, and the magnitude of the effective diamagnetic field received by the storage layer 17 is decreased to be smaller than the saturation magnetization amount Ms of the storage layer 17.

In the embodiment, when the insulating layer 16 that is the intermediate layer is the magnesium oxide layer, it is possible to raise the magnetoresistance change rate (MR rate).

By raising the MR rate as described above, the efficiency of the spin injection is improved, and it is possible to lower the current density necessary to reverse the direction of magnetization M1 of the storage layer 17.

The storage element 3 of the embodiment may be produced by continuously forming the base layer 14 to the cap layer 18 in a vacuum device, and then forming the pattern of the storage element 3 by a process such as etching.

According to the embodiment described above, since the storage layer 17 of the storage element 3 is configured such that the magnitude of the effective diamagnetic field received by the storage layer 17 is smaller than the saturation magnetization amount Ms of the storage layer 17, the diamagnetic field received by the storage layer 17 becomes low, and thus it is possible to reduce the amount of writing electric current necessary to reverse the direction of magnetization M17 of the storage layer 17.

Meanwhile, since it is possible to reduce the amount of writing electric current even when the saturation magnetization amount Ms of the storage layer 17 is not reduced, it is possible to sufficiently secure the thermal stability of the storage layer 17 in which the saturation magnetization amount Ms of the storage layer 17 is a sufficient amount.

As described above, since it is possible to sufficiently secure the thermal stability that is the information storing capability, it is possible to configure the storage element 3 with excellent characteristic balance.

Accordingly, it is possible to sufficiently obtain an operation margin of the storage element 3 without an operation error, and it is possible to stably operate the storage element 3.

Therefore, it is possible to realize a stably operating memory device with high reliability.

By reducing the writing electric current, it is possible to reduce the power consumption when the writing is performed on the storage element 3.

Accordingly, it is possible to reduce the overall power consumption of the memory device in which the memory cell is configured by the storage element 3 of the embodiment.

Therefore, since it is possible to realize a stably operating memory device with high reliability, it is possible to reduce the power consumption in the memory device provided with the storage element 3.

The memory device provided with the storage element 3 shown in FIG. 2 and having the configuration shown in FIG. 1 has an advantage capable of applying a general semiconductor MOS forming process when the memory device is produced.

Accordingly, it is possible to apply the memory device of the embodiment as a general purpose memory.

### 3. Specific Configuration 2 of Storage Layer and Magnetization Fixed Layer of Embodiment

Another specific configuration of the storage layer and the magnetization fixed layer of the embodiment will be described. A configuration example of the memory device and the storage element 3 of the embodiment is the same as FIG. 1 and FIG. 2, and thus the description is not repeated.

In the embodiment, similarly to the specific configuration 1, Co—Fe—B is used as the storage layer 17 and the magnetization fixed layer 15, but the composition of Co—Fe—B is (Coₓ—Fe_{y})_{100-z} —B_{z}, where 0≦Coₓ≦40, 60≦Fe_{y}≦100, and 20<B_{z}≦40.

In a case of production of the spin injection type magnetization inversion memory that is a semiconductor device, it is preferable that the magnetic material constituting the storage element 3 exhibit excellent characteristics in a temperature range permitted by the semiconductor process.

For example, thermal load added by a semiconductor process performed until it becomes a chip from an Si substrate through all the processes may be 350° C. or higher. Accordingly, considering it, it is necessary that the magnetic material constituting the storage element 3 have excellent characteristics even when a heat treatment of 350° C. or higher is performed.

Meanwhile, when the transistor necessary for the operation of the memory device is exposed to a high temperature of, for example 450° C. or higher, characteristics thereof deteriorate. For this reason, a magnetic material representing excellent characteristics in a state of heating with a high temperature such as 450° C. and 500° C. is not preferable.

Accordingly, in a case of production of the spin injection type magnetization inversion memory, it is necessary that the magnetic material constituting the storage element 3 represent satisfactory characteristics in a temperature range substantially equal to or higher than 350° C. and lower than 450° C.

From the viewpoint of thermal affinity with the semiconductor process, as for a general perpendicular magnetization material, magnetic and TMR characteristics deteriorate at a high temperature of 250° C. or higher, or magnetic characteristics are present at a high temperature of 500° C. or higher, and thus it is difficult to handle the perpendicular magnetization film.

However, the perpendicular magnetization film is suitable for high capacity and low power consumption as described above. Accordingly, it is important to develop a perpendicular magnetization film for the spin injection type magnetization inversion memory representing the low inversion electric current or high output characteristics in the heat treatment condition of high affinity with the semiconductor processor.

In the memory device using the storage element 3 having the perpendicular magnetic anisotropy suitable for high capacity and low power consumption as described above, the second embodiment is based on the recognition that it is necessary to secure a high magnetoresistance change rate in a range in which the heat treatment temperature is equal to or higher than 350° C. and lower than 450° C.

To reduce the recording electric current as described above, it is preferable to employ the perpendicular magnetization type. Generally, the perpendicular magnetization film can have the magnetic anisotropy higher than that of the in-plane magnetization film, and thus it is preferable in that the thermal stability Δ described above is kept high.

As a magnetic material having the perpendicular anisotropy, there are several kinds of materials such as rare-earth-transition metal alloy (TbCoFe and the like), metal multilayer film (Co/Pd multilayer film and the like), ordered alloy (FePt and the like), and a material (Co/MgO and the like) using an interfacial anisotropy between oxide and magnetic metal. However, when the rare-earth-transition metal alloy is diffused and crystallized by heating, the alloy loses the perpendicular magnetic anisotropy. Accordingly, the alloy is not preferable as the material for the spin injection type magnetization inversion memory. It is known that the metal multilayer film is also diffused by heating and the perpendicular magnetic anisotropy deteriorates, and the perpendicular magnetic anisotropy is further exhibited in a case of face-centered cubic (111) alignment. Accordingly, it is difficult to realize (001) alignment which is necessary to form a high polarization rate layer such as MgO or Fe, CoFe, and CoFeB disposed adjacent thereto.

L10 ordered alloy is stable even at a high temperature, and represents the perpendicular magnetic anisotropy at the time of (001) alignment, and thus the problem described above does not occur. However, it is necessary to regularly arrange atoms by heating at a sufficient high temperature of 500° C. or higher at the time of production or by performing a heat treatment at a high temperature of 500° C. or higher after production, and thus affinity with the semiconductor process is low. Meanwhile, diffusion which is not preferable at the other part of the laminated film such as a tunnel barrier or increase of interfacial roughness may occur.

A material using the interfacial magnetic anisotropy, that is, a material formed by laminating a Co-based or Fe-based material on MgO that is the tunnel barrier does not cause any problem described above. For this reason, the material has a bright future as the storage layer of the spin injection type magnetization inversion memory.

The inventors of the present disclosure have variously examined about that. As a result, in a case of a magnetic material configured by Co—Fe—B, a composition thereof is in a range of [(Coₓ—Fe_{y})_{100-z} —B_{z}], where 0≦Coₓ≦40, 60≦Fe_{y}≦100, and 20<B_{z}≦40, it was found that it is possible to keep the spin polarization rate P in the formula representing the inversion electric current described above high even in a state where the heat treatment temperature is equal to or higher than 350° C.

The high output element has the high spin polarization rate P, and thus it is possible to achieve a low inversion electric current according to the embodiment.

By using the perpendicular magnetization material having the high magnetic anisotropy, it is possible to provide the spin injection type magnetization inversion element (storage element 3) with high output and low power consumption without a sacrifice of the thermal stability.

The configuration of the memory device and the storage element 3 of the second embodiment is the same as FIG. 1 and FIG. 2, but the storage layer 17 of the storage element 3 has the composition described above.

That is, according to the storage element of the second embodiment, the storage layer 17 that stores information by a magnetization state of a magnetic body is provided, and the storage layer 17 is provided with the magnetization fixed layer 15 through the insulating layer 16 that is the intermediate layer. By injecting spin-polarized electrons in the lamination direction, the direction of magnetization of the storage layer 17 magnetized in the film face perpendicular direction is changed to record the information on the storage layer 17. As a ferromagnetic layer material constituting the storage layer 17, for example, by using Co—Fe—B of the composition described above, it is possible to obtain the high tunnel magnetoresistance effect and the low inversion electric current characteristics even in the high temperature heat treatment.

Accordingly, even in high temperature heat treatment, it is possible to achieve magnetization inversion with a high output and using the low electric current.

In the memory device using the storage element 3, the electric current flows in the storage element 3 in the lamination direction through two kinds of lines (the lines 1 and 6 shown in FIG. 1), and spin transfer occurs. Accordingly, it is possible to perform the recording of information based on the spin torque magnetization inversion by causing electric current to flow in the lamination direction of the storage element 3 through two kinds of lines.

In the second embodiment, it is possible to obtain characteristics of high output and low current operation even in the high temperature heat treatment, and thus it is possible to configure the storage element 3 with excellent characteristic balance.

Since the perpendicular magnetization film having high magnetic anisotropy is used, the thermal stability of information does not deteriorate.

Accordingly, the operation error is removed, it is possible to sufficiently obtain the operation margin of the storage element 3, and it is possible to stably operate the storage element 3.

The material is a material representing excellent characteristics in the high temperature heat treatment of 350° C. or higher and lower than 450° C., and thus affinity with the semiconductor process is high.

The writing electric current for the storage element 3 is reduced, and thus it is possible to reduce the power consumption of the storage element.

Accordingly, it is possible to reduce the overall power consumption of the memory device in which the memory cell is configured by the storage element 3 of the embodiment.

Therefore, it is possible to realize the stably operating memory with high reliability.

The memory provided with the storage element 3 shown in FIG. 2 and having the configuration shown in FIG. 1 has an advantage capable of applying a general semiconductor MOS forming process when the memory is produced.

Accordingly, the memory of the embodiment can be applied as a general purpose memory.

The magnetization fixed layer 15 may have the composition of Co—Fe—B.

Even in the embodiment of the specific example 2, when the insulating layer 16 that is the intermediate layer is a magnesium oxide layer, it is possible to raise the magnetoresistance change rate (MR rate).

By raising the MR rate, the efficiency of the spin injection is improved, and it is possible to further lower the current density necessary to reverse the direction of magnetization M17 of the storage layer 17.

The storage element 3 can be produced by continuously forming the base layer 14 to the cap layer 18 in a vacuum device and then forming the pattern of the storage element 3 by a process such as etching.

### 4. Laminated Ferri-Pinned Structure of Magnetization Fixed Layer of Embodiment

The laminated ferri-pinned structure of the magnetization fixed layer of the embodiment will be described. A configuration example of the memory device and the storage device 3 of the embodiment is the same as that of FIG. 1 and FIG. 2, and the description thereof is not repeated.

The magnetization fixed layer 15 is considered a reference of storage of information stored by the storage layer 17. Accordingly, in the magnetization fixed layer 15, the direction of magnetization may not be changed by the recording to the storage layer 17 and the reading from the storage layer 17, and it is not necessary that the direction of magnetization be necessarily fixed in a specific direction.

In magnetic characteristics of the magnetization fixed layer 15, the storage power thereof may be larger than that of the storage layer 17, the film thickness may be large, or the magnetic damping constant may be large, and thus it is preferable that the magnetization characteristics be not more easily moved than the magnetization characteristics of the storage layer 17.

It is conceivable that the structure of the magnetization fixed layer 15 is the laminated ferri-pinned structure to stably fix the magnetization of the magnetization fixed layer 15. That is, the nonmagnetic layer is interposed between the upper and lower ferromagnetic layers, and the upper and lower ferromagnetic layers are magnetically coupled in anti-parallel. A plurality of nonmagnetic layers interposed between the upper and lower ferromagnetic layers, which are magnetically coupled in anti-parallel may be overlapped.

Accordingly, it is possible to block the leakage magnetic field caused by the magnetization fixed layer 15 and to strengthen the perpendicular magnetic anisotropy of the magnetization fixed layer 15.

As a material of the nonmagnetic layer, Ru, Re, Ir, Os, and the like described above may be used.

As a material of the ferromagnetic layer, Co—Fe—B may be used. The composition of Co—Fe—B is (Coₓ—Fe_{y})_{100-z} —B_{z}, where 0≦Coₓ≦40, 60≦Fe_{y}≦100, and 0<B_{z}≦30, and the composition is very preferable to form the magnetization fixed layer of the perpendicular magnetization.

When the heat treatment temperature is a relatively high temperature of about 350° C. to 450° C., the material of the ferromagnetic layer is Co—Fe—B, the composition of Co—Fe—B is (Coₓ—Fe_{y})_{100-z} —B_{z}, where 0≦Coₓ≦40, 60≦Fe_{y}≦100, and 0<B_{z}≦30, and the composition is very preferable to form the magnetization fixed layer of the perpendicular magnetization.

In the plurality of structures in which the nonmagnetic layer is interposed between the upper and lower ferromagnetic layers, it is very preferable that the material of the nonmagnetic layer constituting the structure interposed therebetween on the insulating layer side be Ta.

It is not limited to Ta, but Ru, Os, Re, Ir, Au, Ag, Cu, Al, Bi, Si, B, C, Cr, Pd, Pt, Zr, Hf, W, Mo, Nb, or alloy thereof may be used. It is possible to adjust the magnetic characteristics using them.

### 5. Test about Embodiment

In the configuration of the storage element of the embodiment, specifically, the material of the ferromagnetic layer constituting the storage layer 17 was selected, the magnitude of the effective diamagnetic field received by the storage layer was adjusted, samples of the storage element were produced, and characteristics thereof were examined.

In an actual memory device, as shown in FIG. 1, a switching semiconductor circuit and the like are provided in addition to the storage element 3. However, herein, the examination was performed by a wafer forming only the storage element to investigate the magnetization inversion characteristics of the storage layer 17.

[Test 1]

A thermal oxidization film with a thickness of 300 nm was formed on a silicon substrate with a thickness of 0.725 mm, and the storage element 3 with the configuration shown in FIG. 2 was formed thereon.

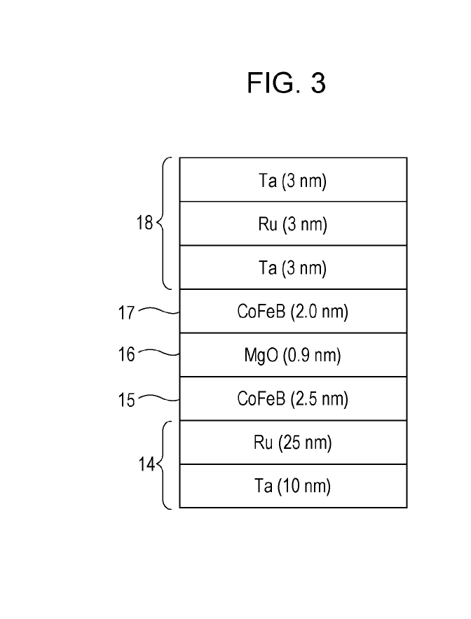

Specifically, in the storage element 3 with the configuration shown in FIG. 2, materials and film thicknesses of layers were selected as shown in FIG. 3.

Base Layer 14: Laminated Film of Ta Film with Film Thickness of 10 nm and Ru Film with Film Thickness of 25 nm

Magnetization Fixed Layer 15: CoFeB Film with Film Thickness of 2.5 nm

Tunnel Insulating Layer 16: Magnesium Oxide Film with Film Thickness of 0.9 nm

Storage Layer 17: CoFeB Film with Same Configuration as Magnetization Fixed Layer

Cap Layer 18: Laminated Film of Ta Film with Film Thickness of 3 nm, Ru Film with Film Thickness of 3 nm, and Ta Film with Film Thickness of 3 nm

The layers were selected as described above, and a Cu film (to be the word line to be described layer) with a film thickness of 100 nm (not shown) was provided between the base layer 14 and the silicon substrate.

With the film configuration described above, the material of the ferromagnetic layer of the storage layer 17 is 3-primary alloy of Co—Fe—B, and the film thickness of the ferromagnetic layer was fixed to 2.0 nm.

The layers other than the insulating layer 16 formed of a magnesium oxide film were formed using a DC magnetron sputtering method.

The insulating layer 16 formed of the magnesium oxide (MgO) film was formed using an RF magnetron sputtering method.

After forming the layers of the storage element 3, a heat treatment was performed in magnetic field heat treatment furnace.

Then, the word line part was masked by photolithography, and then selective etching was performed by Ar plasma on the laminated film at a part other than the word line, to form the word line (lower electrode).

In this case, except for the word line part, the etching was performed up to the 5 nm depth of the substrate.

Thereafter, a mask of a pattern of the storage element 3 was formed by an electronic beam photolithography device, and selective etching was performed on the laminated film, to form the storage element 3. Except for the storage element 3 part, etching was performed up to the immediately above the Cu layer of the word line.

In a storage element for characteristic assessment, since it is necessary to cause sufficient electric current to flow in the storage element to generate a spin torque necessary for the magnetization inversion, it is necessary to suppress the resistance value of the tunnel insulating layer. In the pattern of the storage element 3, the area resistance value (Ωμm²) of the storage element 3 was 20 Ωμm² as an oval shape of the shortest axis of 0.09 μm× the longest axis of 0.18 μm in the oval.

Then, a part other than the storage element 3 part was insulated by sputtering of Al₂O₃ with a thickness of about 100 nm.

Thereafter, a bit line to be the upper electrode and a pad for measurement were formed using photolithography.

As described above, the sample of the storage element 3 was produced.

By the producing method described above, samples of the storage element 3 in which the composition of Co—Fe—B alloy of the ferromagnetic layer of the storage layer 17 was changed were produced.

In the composition of Co—Fe—B alloy, a composition ratio (atom %) of CoFe and B is fixed to 80:20, a composition ratio×(atom %) of Co in CoFe was changed to 90%, 80%, 70%, 60%, 50%, 40%, 30%, 20%, 10%, and 0%.

As described above, in the samples of the produced storage element 3, the assessment of characteristics was performed as follows.

Before measurement, it was configured that magnetic field was applied from the outside the storage element 3 such that it is possible to control values in a plus direction and a minus direction of the inversion electric current to be symmetry.

Voltage applied to the storage element 3 was set up to 1 V in a range in which the insulating layer 16 is not broken.

(Measurement of Saturation Magnetization Amount)

The saturation magnetization amount Ms was measured by VSM measurement using a vibrating sample magnetometer.

(Measurement of Effective Diamagnetic Field)

As a sample for measurement of effective diamagnetic field, the layers constituting the storage element 3 were formed separately from the sample of the storage element 3 described above, and a sample formed in a planar pattern of 20 mm×20 mm square was produced.

A magnitude of effective diamagnetic field Meffective was acquired by FMR (ferromagnetic resonance) measurement.

A resonance frequency fFMR for arbitrary external magnetic field Hex which can be acquired by the FMR measurement is given in the following formula (3).

f_{FMR}=γ′\sqrt{4πMeffective(H_{K}+Hₑₓ)} (3)

Herein, the Meffective in the formula (3) is represented by 4πMeffective=4πMs−H⊥ (H⊥: anisotropy magnetic field in a direction perpendicular to a film face).

(Measurement of Inversion Current Value and Thermal Stability)

To assess the writing characteristics of the storage element 3 according to the embodiment, measurement of the inversion current value was performed.

Electric current of a pulse width of 10 μs to 100 ms was caused to flow in the storage element 3, and then the resistance value of the storage element 3 was measured.

The amount of electric current flowing in the storage element 3 was changed, and the current value in which the direction of magnetization M17 of the storage layer 17 of the storage element 3 was acquired. A value obtained by inserting dependency of the pulse width of the current value to the outside in a pulse width of 1 ns was the inversion current value.

A slope of the dependency of the pulse width of the inversion current value corresponds to an indicator (A) of the thermal stability of the storage element 3 described above. As the inversion current value is not changed by the pulse width (the slope is small), it means that it is strong against disturbance of heat.

To consider variability among the storage elements 3, about twenty storage elements 3 with the same configuration were produced, the measurement described above was performed, and the average value of the inversion current value and the indicator Δ of the thermal stability was acquired.

The average value of the inversion current value obtained by the measurement, an area of the planar pattern of the storage element 3, and a inversion current density Jc0 were calculated.

In the samples of the storage element 3, the composition of Co—Fe—B alloy of the storage layer 17, the saturation magnetization amount Ms, the measurement result of the magnitude of the effective diamagnetic field Meffective, and a ratio Meffective/Ms of the saturation magnetization amount and the magnitude of the effective diamagnetic field are shown in Table 1. Herein, the content of Co of the Co—Fe—B alloy of the storage layer 17 described in Table 1 is represented by atom %.

TABLE 1

| | Ms(emu/cc) | Meffctive(emu/cc) | Meffective/Ms |
|---|---|---|---|
| (Co₉₀Fe₁₀)₈₀—B₂₀ | 960 | 1210 | 1.26 |
| (Co₈₀Fe₂₀)₈₀—B₂₀ | 960 | 1010 | 1.05 |
| (Co₇₀Fe₃₀)₈₀—B₂₀ | 1040 | 900 | 0.87 |
| (Co₆₀Fe₄₀)₈₀—B₂₀ | 1200 | 830 | 0.69 |
| (Co₅₀Fe₅₀)₈₀—B₂₀ | 1300 | 690 | 0.53 |
| (Co₄₀Fe₆₀)₈₀—B₂₀ | 1300 | 500 | 0.38 |
| (Co₃₀Fe₇₀)₈₀—B₂₀ | 1260 | 390 | 0.31 |
| (Co₂₀Fe₈₀)₈₀—B₂₀ | 1230 | 360 | 0.29 |
| (Co₁₀Fe₉₀)₈₀—B₂₀ | 1200 | 345 | 0.29 |
| Fe₈₀—B₂₀ | 1160 | 325 | 0.28 |

From Table 1, when the content x of Co of (CoₓFe₁₀₀₋ₓ)₈₀B₂₀ is equal to or less than 70%, the magnitude (Meffective) of the effective diamagnetic field is smaller than the saturation magnetization amount Ms, that is, the ratio Meffective/Ms when the content x of Co is equal to or less than 70% is a value smaller than 1.0.

It can be confirmed that a difference between Meffective and Ms increases as the content x of Co decreases.

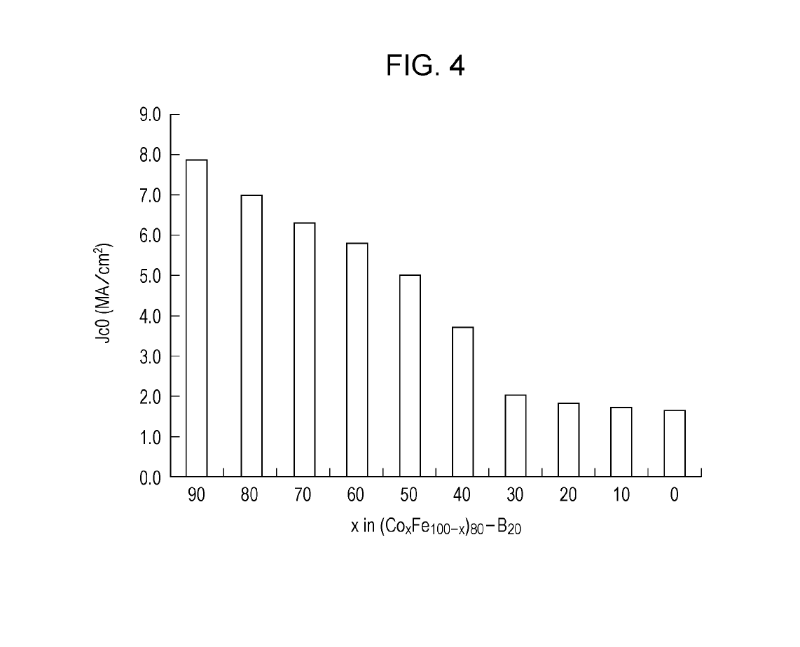

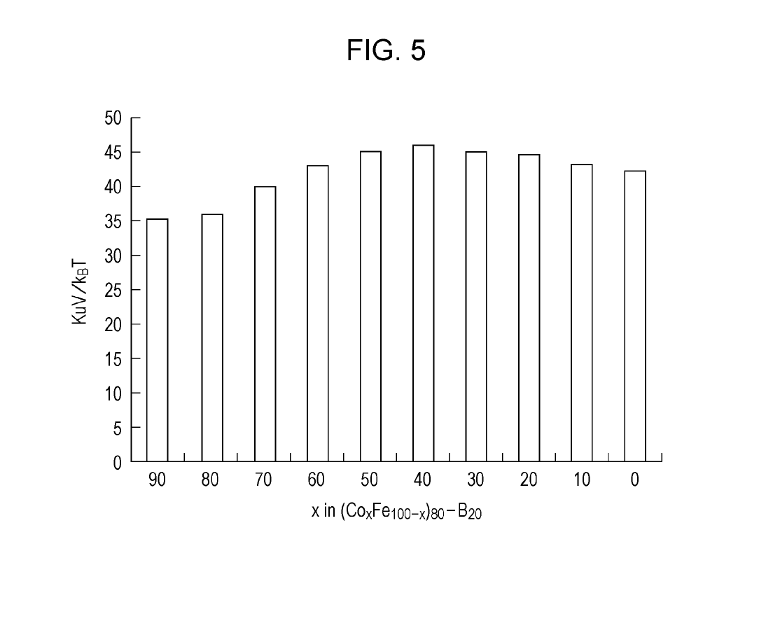

The measurement result of the inversion current value is shown in FIG. 4, and the measurement result of the indicator of the thermal stability is shown in FIG. 5.

FIG. 4 shows a relationship between the content x (content in CoFe: atom %) of Co—Fe—B alloy of the storage layer 17 and the inversion current density Jc0 acquired from the inversion current value.

FIG. 5 shows a relationship between the content (content in CoFe: atom %) of Co of Co—Fe—B alloy of the storage layer 17 and the indicator Δ (KV/k_{B}T) of the thermal stability.

From FIG. 4, it can be found that the inversion current density Jc0 gets lower as the content x of Co gets smaller.

The reason is because the saturation magnetization amount Ms is increased when the content x of Co becomes small, but the effective diamagnetic field Meffective becomes small, and thus a product of both (Ms×Meffective) becomes small.

From FIG. 5, it is found that the indicator Δ (=KV/k_{B}T) of the thermal stability gets larger as the content x of Co gets smaller, and the indicator Δ of the thermal stability is stabilized to a large value when the content x of Co becomes small to some extent.

This coincides with the expected change such as the measurement result of the saturation magnetization amount Ms shown in FIG. 5 and the proportion of the indicator Δ of the thermal stability to the saturation magnetization amount Ms from the formula (2).

From the result of Table 1, FIG. 4, and FIG. 5, it was found that it is possible to reduce the inversion current value Jc0 with high thermal stability without using a method of sacrificing the thermal stability to decrease Ms in the composition in which the content x of Co is equal to or less than 70%, in which the effective diamagnetic field Meffective becomes smaller than the saturation magnetization amount Ms.

[Test 2]

By the [Test 1] described above, it can be found that, in the case of (CoₓFe₁₀₀₋ₓ)₈₀B₂₀, it is possible to reduce the inversion current value Jc0 with a configuration in which the content x of Co is equal to or less than 70% with high thermal stability.

In the [Test 2], an influence of the content z of B on the ratio of Co and Fe and the Meffective/Ms was examined using the storage layer 17 with the composition of (Co₇₀Fe₃₀)₈₀B_{z} and (Co₈₀Fe₂₀)₈₀B_{z}. Details of samples are the same as the [Test 1].

In Table 2, in (Co₇₀Fe₃₀)_{100-z}—B_{z}, the composition of CoFeB alloy in which the content z of B (atom %) is 5 to 40%, the saturation magnetization amount Ms, the measurement result of the magnitude of effective diamagnetic field Meffective, and the ratio Meffective/Ms of the saturation magnetization amount and the magnitude of the effective diamagnetic field are shown.

In Table 3, in (Co₈₀Fe₂₀)_{100-z}—B_{z}, similarly, the composition of CoFeB alloy in which the content z of B (atom %) is 5 to 40%, the saturation magnetization amount Ms, the magnitude of the effective diamagnetic field Meffective, and the ratio Meffective/Ms are shown.

TABLE 2

| | Ms(emu/cc) | Meffective(emu/cc) | Meffective/Ms |
|---|---|---|---|
| (Co₇₀Fe₃₀)₉₅—B₅ | 1310 | 1090 | 0.83 |
| (Co₇₀Fe₃₀)₉₀—B₁₀ | 1250 | 1080 | 0.89 |
| (Co₇₀Fe₃₀)₈₀—B₂₀ | 1040 | 900 | 0.87 |
| (Co₇₀Fe₃₀)₇₀—B₃₀ | 820 | 730 | 0.89 |
| (Co₇₀Fe₃₀)₆₀—B₄₀ | 450 | 690 | 1.53 |

TABLE 3

| | Ms(emu/cc) | Meffective(emu/cc) | Meffective/Ms |
|---|---|---|---|
| (Co₈₀Fe₂₀)₉₅—B₅ | 1250 | 1280 | 1.02 |
| (Co₈₀Fe₂₀)₉₀—B₁₀ | 1100 | 1140 | 1.04 |
| (Co₈₀Fe₂₀)₈₀—B₂₀ | 960 | 1010 | 1.05 |
| (Co₈₀Fe₂₀)₇₀—B₃₀ | 750 | 890 | 1.19 |
| (Co₈₀Fe₂₀)₆₀—B₄₀ | 430 | 690 | 1.60 |

From the result of Table 2, when the ratio of Co and Fe is fixed to 70/30 such as (Co₇₀Fe₃)_{100-z}—B_{z}, it can be confirmed that the effective diamagnetic field Meffective is smaller than the saturation magnetization amount Ms in the composition other than the content z=40 atom % of B.

From the result of Table 3, when the ratio of Co and Fe is fixed to 80/20 such as (Co₈₀Fe₂₀)_{100-z}—B_{z}, it can be confirmed that the effective diamagnetic field Meffective is larger than the saturation magnetization amount Ms in any composition.

From the results of Table 1 to 3 described above, when the content z of B is in the range of 30 atom % or less, it was found that the magnitude relation of the saturation magnetization amount Ms and the effective diamagnetic field Meffective is determined by the ratio of Co and Fe.

Accordingly, the composition of Co—Fe—B alloy in which the effective diamagnetic field Meffective of the storage layer 17 becomes smaller than the saturation magnetization amount Ms is (Coₓ—Fe_{y})_{100-z}—B_{z}, where 0≦Coₓ70, 30≦Fe_{y}≦100, and 0<B_{z}≦30.

[Test 3]

In the spin injection type magnetization inversion memory of Gbit class, it is assumed that the size of the storage element is equal to or less than 100 nmφ. In the [Test 3], the thermal stability was assessed using the storage element with a size of 50 nmφ.

In the composition of Co—Fe—B alloy, a composition ratio (atom %) of CoFe and B is fixed to 80:20, a composition ratio×(atom %) of Co in CoFe was changed to 90%, 80%, 70%, 60%, 50%, 40%, 30%, 20%, 10%, and 0%.

Details of samples other than the element size are the same as the [Test 1].

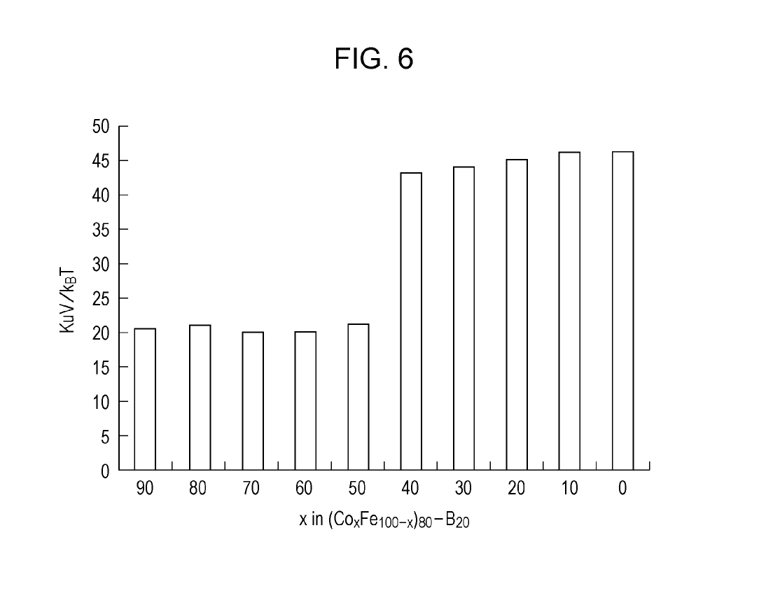

The relationship of the content of Co (content in CoFe: atom %) of Co—Fe—B alloy and the indicator Δ (KV/k_{B}T) of the thermal stability when the size of the storage element 3 is 50 nmφ is shown in FIG. 6.

From FIG. 6, since the element size is 50 nmφ, it is found that dependency of the Co—Fe—B alloy composition of the thermal stability indicator Δ is drastically changed from the Co—Fe—B alloy composition dependency of Δ obtained by the oval shape storage element shown in FIG. 4 whose shortest axis is 0.09 μm and longest axis is 0.18 μm.

According to FIG. 6, only in the case of the Co—Fe—B alloy composition in which Fe is present equal to or more than 60 atom %, high thermal stability is kept.

As a result of various studies, it was found that the reason why the high thermal stability Δ is represented in the storage element in which the Co—Fe—B alloy where Fe is present equal to or more than 60 atom % is very small, is because the magnetization of the Co—Fe—B alloy is directed to the film face perpendicular direction.

It is though that the reason why the magnetization of the Co—Fe—B alloy is directed to the film face perpendicular direction is caused by the configuration in which the effective diamagnetic field Meffective is significantly smaller than the saturation magnetization amount Ms.

In the case of the perpendicular magnetization film, the reason why the thermal stability is kept even in the very small element relates to Hk [effective anisotropy magnetic field] in the formula (2), and the Hk of the perpendicular magnetization film generally becomes a value even larger than that of the in-plane magnetization film. That is, in the perpendicular magnetization film, by the effect of the large Hk, it is possible to keep the thermal stability Δ even in the very small element in which it is difficult to secure the high thermal stability Δ.

From the test result, in the Co—Fe—B alloy with the configuration of (CoₓFe₁₀₀₋ₓ)₈₀B₂₀, when Fe₁₀₀₋ₓ is equal to or more than 60, it is suitable for the memory device using the spin injection of Gbit class.

[Test 4]

In the [Test 3], it is shown that, in the Co—Fe—B alloy with the configuration of (CoₓFe₁₀₀₋ₓ)₈₀B₂₀, when the content of Fe is equal to or more than 60, it is suitable for the memory device using the spin injection of Gbit class. In the [Test 4], the storage element with the size of 50 nmφ was produced with the Co—Fe—B alloy in which the content of B is in the range of 5 to 30 atom %, and the thermal stability was assessed.

Details of samples other than the element size are the same as the [Test 1].

A relationship between the Co—Fe—B alloy with the configuration of (CoₓFe₁₀₀₋ₓ)_{100-z}B_{z} in the range where the content x of Co is 50, 40, 30, 20, 10, and 0, and the content z of B is 5, 10, 20, and 30, and the indicator Δ (KV/k_{B}T) of the thermal stability is shown in Table 4.

TABLE 4

| | (Co₅₀—Fe₅₀)_{100-z}—B_{z}) | (Co₄₀—Fe₆₀)_{100-z}—B_{z}) | (Co₃₀—Fe₇₀)_{100-z}—B_{z}) |
|---|---|---|---|
| Bz = 5 Atom % | 19 | 40 | 42 |
| Bz = 10 Atom % | 20 | 41.5 | 43 |
| Bz = 15 Atom % | 20 | 43 | 44 |
| Bz = 20 Atom % | 21 | 45 | 47 |

| | (Co₂₀—Fe₈₀)_{100-z}—B_{z}) | (Co₁₀—Fe₉₀)_{100-z}—B_{z}) | Fe_{100-z}—B_{z} |
|---|---|---|---|
| Bz = 5 Atom % | 42 | 43 | 44 |
| Bz = 10 Atom % | 44 | 44 | 45 |
| Bz = 15 Atom % | 45 | 46 | 46 |
| Bz = 20 Atom % | 48 | 48 | 48 |

From Table 4, it is found that the thermal stability Δ is kept high in all the compositions except for the case of Co content x is 50% and B content z is 5 to 30%.

That is, similarly to the result of [Test 4], it was found that the Co content x=50 and 60 becomes a boundary when the high thermal stability is secured in the very small element corresponding to the spin injection type magnetization inversion memory of Gbit class.

Accordingly, from the result, when the composition of Co—Fe—B alloy of the storage layer 17 is (Coₓ—Fe_{y})_{100-z}—B_{z} where 0≦Coₓ≦40, 60≦Fe_{y}≦100, and 0<B_{z}≦30, it was found that it is very suitable to produce the spin injection type magnetization inversion memory of Gbit class.

In the Co—Fe—B alloy, in the composition in which Fe is large in the ratio of Co and Fe, dissociation between the effective diamagnetic field Meffective and the saturation magnetization amount Ms becomes large, it is easy to perform the perpendicular magnetization, and thus it is easy to secure the thermal stability.

For this reason, when capacity of the magnetic memory is increased and the size of the storage element 3 becomes small, it is easy to secure the thermal stability in the Co—Fe—B alloy including a large amount of Fe.

For example, in a situation where the spin injection type magnetic memory of Gbit class can be realized with the storage layer 17 in which Fe_{y} is 60 and 70 nmφ, it is preferable that the content y of Fe of the Co—Fe—B alloy be increased by 5 whenever the diameter of the storage element 3 is decreased by 5 nmφ.

For example, in the content y of Fe, in the case of (Coₓ—Fe_{y})_{100-z}—B_{z}, a case where atom % is in the composition as the content in CoFe is 65%, 70%, 75%, 80%, . . . (in the case of Co content x, 35%, 30%, 25%, 20%, . . . ) is a very suitable example according to the reduction of the size of the storage element.

[Test 5]

In the configuration of the storage element 3 of the embodiment, specifically, the material of the ferromagnetic layer constituting the storage layer 17 was selected, and characteristics of the storage element 3 were examined.

As shown in the [Test 1] to [Test 4], the examination was performed by a wafer forming only the storage element 3 to investigate the magnetization inversion characteristics of the storage layer 17.

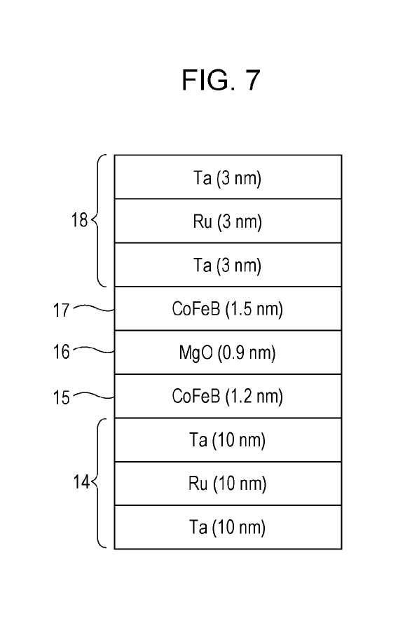

A thermal oxidization film with a thickness of 300 nm was formed on a silicon substrate with a thickness of 0.725 mm, and the storage element 3 with the configuration shown in FIG. 2 was formed thereon, as shown in FIG. 7.

Base Layer 14: Laminated Film of Ta Film with Film Thickness of 10 nm, Ru Film with Film Thickness of 10 nm, and Ta Film with Film Thickness of 10 nm

Magnetization Fixed Layer 15: CoFeB Film with Film Thickness of 1.2 nm

Tunnel Insulating Layer 16: Magnesium Oxide Film with Film Thickness of 0.9 nm

Storage Layer 17: CoFeB Film with Same Configuration as Magnetization Fixed Layer

Cap Layer 18: Laminated Film of Ta Film with Film Thickness of 3 nm, Ru Film with Film Thickness of 3 nm, and Ta Film with Film Thickness of 3 nm

The layers were selected as described above, a Cu film (to be the word line to be described layer) with a film thickness of 100 nm (not shown) was provided between the base layer 14 and the silicon substrate, and the layers were formed.

With the film configuration described above, the material of the ferromagnetic layer of the storage layer 17 is 3-primary alloy of Co—Fe—B, and the film thickness of the ferromagnetic layer was fixed to 1.5 nm.

The layers other than the insulating layer 16 formed of a magnesium oxide film were formed using a DC magnetron sputtering method.

The insulating layer 16 formed of the magnesium oxide (MgO) film was formed using an RF magnetron sputtering method.

After forming the layers of the storage element 3, a heat treatment was performed in a heat treatment furnace in a magnetic field, at various temperatures for one hour.

Then, the word line part was masked by photolithography, and then selective etching was performed by Ar plasma on the laminated film at a part other than the word line, to form the word line (lower electrode). In this case, except for the word line part, the etching was performed up to the 5 nm depth of the substrate.

Thereafter, a mask of a pattern of the storage element 3 was formed by an electronic beam photolithography device, and selective etching was performed on the laminated film, to form the storage element 3. Except for the storage element 3 part, etching was performed up to the immediately above the Cu layer of the word line.

In a storage element for characteristic assessment, since it is necessary to cause sufficient electric current to flow in the storage element to generate a spin torque necessary for the magnetization inversion, it is necessary to suppress the resistance value of the tunnel insulating layer. In the pattern of the storage element 3, the area resistance value (Ωμm²) of the storage element 3 was 20 Ωμm² as an oval shape of the shortest axis of 0.09 μm× the longest axis of 0.09 μm in the oval.

Then, a part other than the storage element 3 part was insulated by sputtering of Al₂O₃ with a thickness of about 100 nm.

Thereafter, a bit line to be the upper electrode and a pad for measurement were formed using photolithography.

As described above, the sample of the storage element 3 was produced.

By the producing method described above, samples of the storage element 3 in which the composition of Co—Fe—B alloy of the ferromagnetic layer of the storage layer 17 was changed were produced.

In the composition of Co—Fe—B alloy, a composition ratio (atom %) of Co and Fe is fixed to 20:80, a composition ratio z (atom %) of B was changed to 10%, 20%, 30%, 35%, 40%, and 50%.

As described above, in the samples of the produced storage element 3, the assessment of characteristics was performed as follows.

(TMR Measurement)

TMR measurement was performed to assess the output characteristics of the storage element according to the present disclosure.

Voltage of 100 mV was applied while leaving magnetic field in a range of 3 kOe in the storage element 3, and the resistance value of the storage element 3 was measured.

To consider the gap between storage elements 3, about twenty storage elements 3 with the same configuration were produced, the measurement described above was performed, and the average value of the characteristics was acquired.

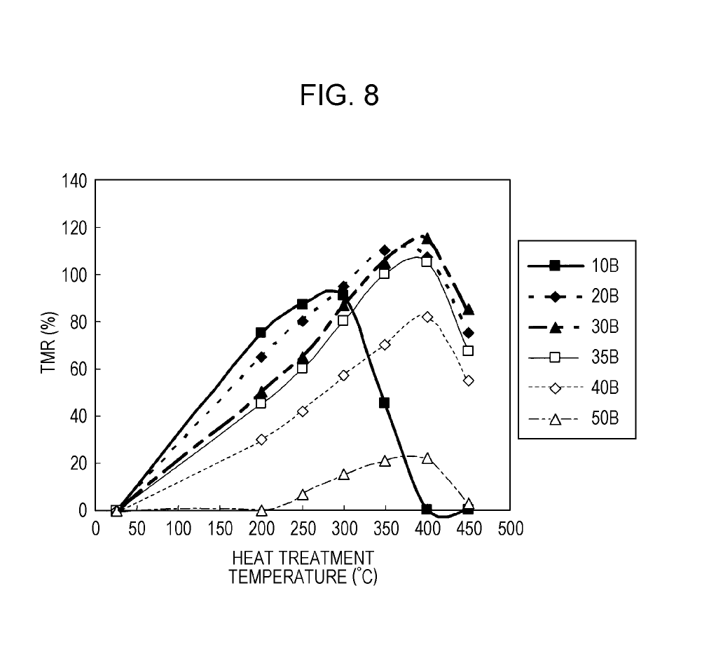

In the samples of the storage element 3, the heat treatment temperature dependency of TMR for each composition of the Co—Fe—B alloy of the storage layer 17 is shown in FIG. 8.

From FIG. 8, in a case of B density of 10% [10B in the graph], it is found that TMR takes a peak in the vicinity of heat treatment temperature: 300° C.

In a case of the composition range of B density of 20 to 40% [20B to 40B in the figure], the peak of TMR is shifted to the vicinity of the heat treatment temperature of 350 to 400° C.

In a case of B density of 50% [50B in the figure], when the heat treatment is equal to or higher than 200° C., TMR is observed, but it is found that an absolute value of TMR becomes drastically small as compared with the Co—Fe—B alloy with the other composition.

In a case of B density of 40%, the B density stays in slightly small TMR as compared with the maximum TMR [about 110%] of the sample of 10 to 35%, but TMR of about 80% is secured in the vicinity of the heat treatment temperature of 350 to 400° C., and it reaches an output applicable for the spin injection type magnetization inversion memory.

In the sample of B density of 20 to 30%, sufficient TMR is secured in the vicinity of 450° C.

In conclusion, in the case of the composition range of B density of 20 to 40%, it can be confirmed that it is possible to obtain the most satisfactory TMR characteristics in the heat treatment range which is most suitable for the semiconductor process.

Generally, when the tunnel magnetic junction is made using the Co—Fe—B alloy, it is found that B is diffused to MgO barrier (insulating layer 16) or the cap layer 18 side by the heat treatment. The reason why it is most suitable that the B density is 20 to 40% in the range of the heat treatment temperature of 350° C. to 400° C. relates to the diffusion of B, and is expected because a regular amount of B as the initial Co—Fe—B alloy composition is present in the alloy film, distribution of B in which excellent perpendicular magnetic characteristics and TMR characteristics can be obtained in a desired heat treatment temperature range is realized, and thus an interfacial magnetic anisotropy of the MgO barrier and the Co—Fe—B alloy is strengthened.

According to the expectation, the B density in which the excellent TMR characteristics can be obtained even in the high temperature heat treatment of 450° C. or higher is present. However, in the case of the sample used in the test, it is thought that roughness of the base layer 14 is increased in the heat treatment over 450° C., the further excessive diffusion of the base layer 14 and the cap layer 18 occurs, and thus the TMR characteristics deteriorates in Co—Fe—B of all the B density.

When the B density is 10%, it is thought that the reason why the TMR characteristics deteriorate in the high temperature of 350° C. or higher is because the B density in the case of performing the heat treatment at the high temperature is too low, and thus it is difficult to strengthen the interfacial magnetic anisotropy of the MgO barrier and the Co—Fe—B alloy.

When the B density is 50%, it is expected that the reason why it is difficult to obtain the satisfactory TMR characteristics is because the B density is too high and the saturation magnetization is drastically decreased.

From the result described above, in the case of Co—Fe—B alloy in which the composition ratio (atom %) of Co and Fe is fixed to 20:80, it was actually verified that it is possible to produce the storage element 3 with high output in the B density of 20 to 40% in the range of the heat treatment temperature of 350° C. to 450° C.

[Test 6]

In the [Test 5], a detailed test result is shown when the B density was changed to a specific Co/Fe ratio. Then, in the [Test 6], the Co/Fe ratio is 40/60, 30/70, and 10/90, the storage element 17 was produced in which the B density is changed to 20%, 30%, and 40%, respectively, and the assessment of TMR characteristics was performed.

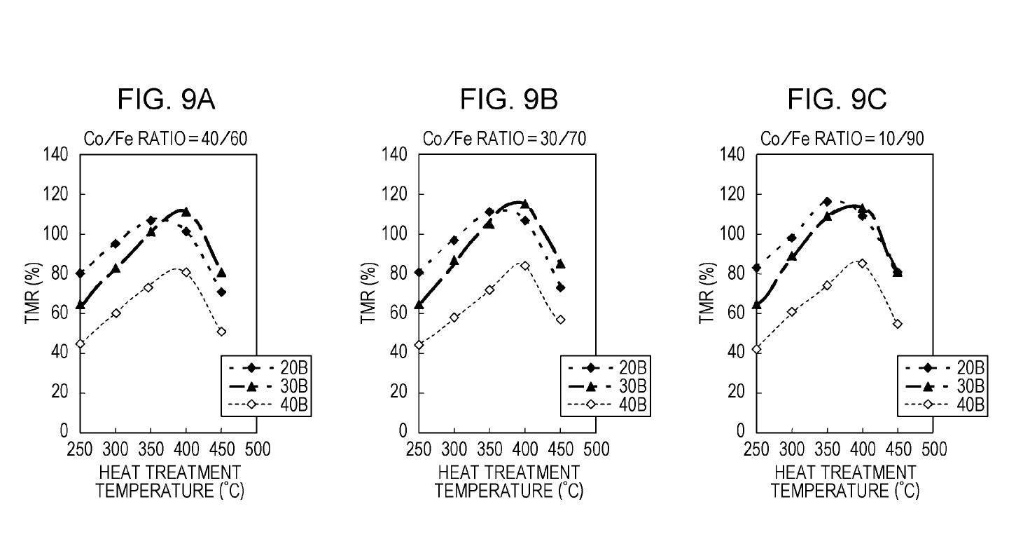

In FIG. 9A, FIG. 9B, and FIG. 9C, the TMR characteristics are shown when the B density and the heat treatment temperature were changed at each Co/Fe ratio.

As shown in the result, even in any composition, it is possible to obtain the high output [=high TMR] in the B density [20 to 40%] shown in the [Test 5] in the heat treatment range [350° C. to 400° C.]

It is possible to see the composition of the high output [=high TMR] in the vicinity of 450° C. For example, it is a composition in which the B density is 20 to 30%.

In the TMR value, high dependency for the Co/Fe ratio is not observed.

From the result of the [Test 5] and [Test 6] described above, by using the perpendicular magnetization ferromagnetic material Co—Fe—B with the composition of (Coₓ—Fe_{y})_{100-z}—B_{Z} where 0≦Coₓ40, 60≦Fe_{y}≦100, and 20<B_{z}≦40, it is possible to provide the high output storage element in the heat treatment temperature range of 350° C. to 400° C. with high affinity with the semiconductor process.

By realizing the high output, the high spin polarization rate P is realized, and thus it is possible to achieve the low power consumption.

As described above, by utilizing the high magnetic anisotropy of the perpendicular magnetization, it is possible to provide the spin injection magnetization inversion element with high output and low inversion electric current without using the method of sacrificing the thermal stability.

In the first embodiment, in the B density, the effective diamagnetic field Meffective becomes smaller than the saturation magnetization amount Ms in the range of 0<B_{z}≦30, and it is very suitable for the perpendicular magnetization (for example, see Table 2). Accordingly, in the second embodiment, in the B density, in the case of 20<B_{z}≦40, it seems that the range of 30 to 40% is not proper.

However, when the relatively high temperature heat treatment is performed, even when the B density is in the range of 30 to 40%, it was found that the effective diamagnetic field Meffective becomes smaller than the saturation magnetization amount Ms, and it is very suitable for the perpendicular magnetization.

The following [Table 5] shows examination of the saturation magnetization amount Ms and the effective diamagnetic field Meffective at the heat treatment temperature of 400° C. when the Co—Fe—B composition of the storage layer 17 is (Co₇₀—Fe₃₀)₆₅—B₃₅ and (Co₇₀—Fe₃₀)₆₀—B₄₀.

TABLE 5

| | Ms(emu/cc) | Meffective(emu/cc) | Meffective/Ms |
|---|---|---|---|
| (Co₇₀Fe₃₀)₆₅—B₃₅ | 740 | 650 | 0.88 |
| (Co₇₀Fe₃₀)₆₀—B₄₀ | 720 | 550 | 0.89 |

Even in any case of the B density of 35% and 40%, the effective diamagnetic field Meffective is smaller than the saturation magnetization amount Ms (Meffective/Ms<1).

That is, when the heat treatment temperature is high, even in the range in which the B density is 30 to 40%, it is satisfied that the magnitude of the effective diamagnetic field received by the storage layer 17 is smaller than the saturation magnetization amount of the storage layer 17.

[Test 7]

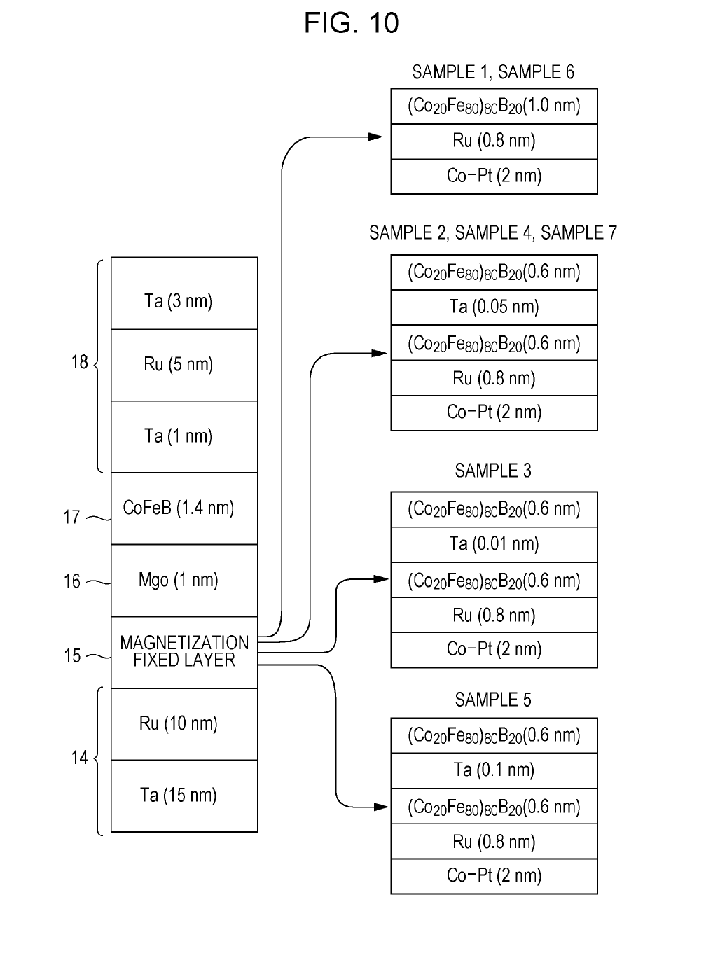

In the test, the magnetization fixed layer 15 of the storage element 3 shown in FIG. 2 has the laminated ferri-pinned structure, and a magnetization curve is acquired when a heat treatment was performed at 300° C. for one hour and when a heat treatment was performed at 350° C. for one hour, on the storage element 3. FIG. 10 is a diagram illustrating a layer structure of a sample of the storage element 3 used in the test. In the test, two kinds of sample 1 and sample 2 were used. The layer structure of the magnetization fixed layer 15 of each sample is as shown in FIG. 10. That is, the sample 1 has a structure in which a nonmagnetic layer of Ru is interposed between ferromagnetic layers of Co—Fe—B and Co—Pt.

The sample 2 is formed by laminating a nonmagnetic layer of Ta which is interposed between ferromagnetic layers of Co—Fe—B in the sample 1.

The layers other than the magnetization fixed layer 15 are as shown in FIG. 10.

In each sample, a thermal oxide film with a thickness of 300 nm was formed on a silicon substrate with a thickness of 0.725 mm, and the storage element 3 shown in FIG. 10 was formed thereon.

A Cu film with a film thickness of 100 nm (not shown) was provided between the base layer and the silicon substrate (becomes a word line to be described layer).

The layers other than the insulating layer 16 were formed by the DC magnetron sputtering method. Since the insulating layer was formed of MgO, and it was formed by the RF magnetron sputtering method. After the layers of the storage element 3 were formed, a heat treatment was performed at 300° C. for one hour or at 350° C. for one hour in a magnetic field heating furnace. The storage element 3 was not an element after a micro-process, and a bulk film part of about 8 mm×8 mm provided for magnetization curve assessment on a wafer was used.

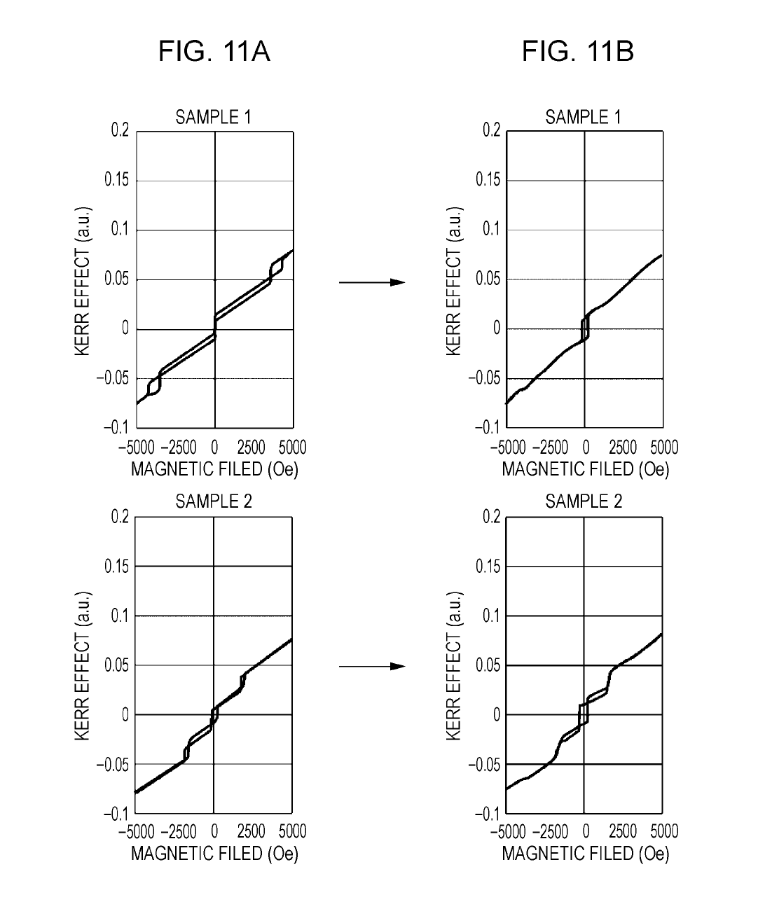

FIG. 11A and FIG. 11B show a magnetization curve for the sample 1 and the sample 2. The magnetization curve is to measure the Kerr effect by applying magnetic field in the film face perpendicular direction of each sample. In the figures, the horizontal axis indicates a magnitude of magnetic field, and the vertical axis indicates a magnitude of the measured Kerr effect.

FIG. 11A is a test result after a heat treatment of 300° C. FIG. 11B is a test result after a heat treatment of 350° C. In FIG. 11A, the sample 1 and the sample 2 are not different in shape of the magnetization curve from each other. This represents that there is no difference in the magnetization curve indicated by the laminated ferri-pinned structure according to whether or not there is Ta.

In FIG. 11B, in the sample 1, the in-plane component is strengthened, the laminated ferri-pinned structure deteriorates, and the perpendicular magnetic anisotropy disappears. On the contrary, in the sample 2, the perpendicular magnetic anisotropy is kept, and the deterioration of the laminated ferri-pinned structure is not shown. In the case of the laminated ferri-pinned structure formed by overlapping a plurality of nonmagnetic layers interposed between the upper and lower ferromagnetic layers, it is shown that the perpendicular magnetic anisotropy is kept even when the heat treatment temperature is high.

In the case of the laminated ferri-pinned structure formed by overlapping the plurality of nonmagnetic layers interposed between the upper and lower ferromagnetic layers, it is possible to increase the film thickness of Co—Fe—B that is a material of the ferromagnetic layer and to improve the MR ratio.

By adding the nonmagnetic layer such as Ta to Co—Fe—B, it serves as diamagnetic field disturbing the perpendicular magnetization, and it is possible to suppress the saturation magnetization Ms of Co—Fe—B, even when the heat treatment temperature is high.

In the test, the composition of B of Co—Fe—B was 20%, but the composition of B may be equal to or more than 20% from the relationship with the heat treatment temperature.

The material of the nonmagnetic layer is not limited to Ta. As the material of the nonmagnetic layer, Ru, Os, Re, Ir, Au, Ag, Cu, Al, Bi, Si, B, C, Cr, Pd, Pt, Zr, Hf, W, Mo, Nb, or alloy thereof may be used. It is possible to adjust the magnetic characteristics using them.

[Test 8]

In the test, the magnetization fixed layer 15 of the storage element 3 shown in FIG. 2 has the laminated ferri-pinned structure, and the change of the magnetization curve is examined when the film thickness of the ferromagnetic layer stands as it is and the film thickness of the nonmagnetic layer was changed. FIG. 10 shows the layer structure of the sample of the storage element 3 used in the test. In the test, three kinds of sample 3, sample 4, and sample 5 shown in FIG. 10 were used. The sample 4 has the same composition and structure as those of the sample 2.

In each sample, a thermal oxide film with a thickness of 300 nm was formed on a silicon substrate with a thickness of 0.725 mm, and the storage element 3 shown in FIG. 10 was formed thereon.

A Cu film with a film thickness of 100 nm (not shown) was provided between the base layer and the silicon substrate (becomes a word line to be described layer).

The layers other than the insulating layer 16 were formed by the DC magnetron sputtering method. Since the insulating layer was formed of MgO, and it was formed by the RF magnetron sputtering method. After the layers of the storage element 3 were formed, a heat treatment was performed at 350° C. for one hour in a magnetic field heating furnace. The storage element 3 was not an element after a micro-process, and a bulk film part of about 8 mm×8 mm provided for magnetization curve assessment on a wafer was used.

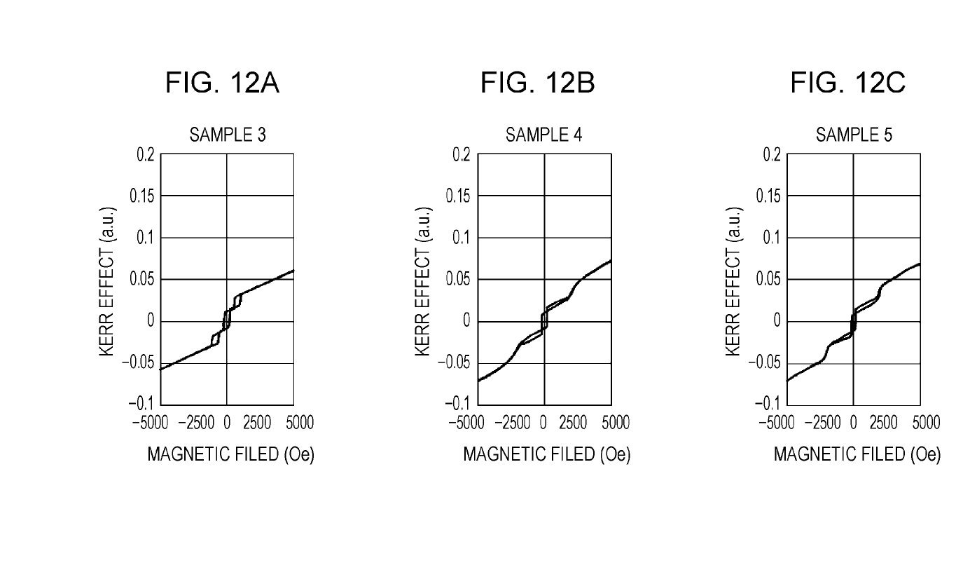

FIG. 12A, FIG. 12B, and FIG. 12C show magnetization curves of the sample 3, the sample 4, and the sample 5, respectively. The magnetization curve can be acquired by measuring the Kerr effect by applying magnetic field in the film face perpendicular direction of each sample. In the figure, the horizontal axis indicates a magnitude of magnetic field, and the vertical axis indicates a magnitude of the measured Kerr effect.

As shown in FIG. 12A, FIG. 12B, and FIG. 12C, even when the film thickness of Ta that is the nonmagnetic layer is increased to 0.1 nm, the deterioration of the laminated ferri-pinned structure is not shown. For this reason, the film thickness of the nonmagnetic layer may be increased in a range in which the magnetization of Co—Fe—B that is the ferromagnetic layer does not disappear, for example, with 0.1 nm.

[Test 9]

In the test, the magnetization fixed layer 15 of the storage element 3 shown in FIG. 2 has the laminated ferri-pinned structure, and the measurement of the thermal stability from the magnetoresistance curve and the inversion current value is performed. In FIG. 10, the layer structure of the sample of the storage element 3 used in the test is shown. In the test, two kinds of sample 6 and sample 7 were used. The layer structure of the magnetization fixed layer 15 of each sample is as shown in FIG. 10. The sample 6 has the same composition structure as the sample 1. The sample 7 has the composition structure as the sample 2. The layers other than magnetization fixed layer 15 are as shown in FIG. 10.

In each sample, a thermal oxidization film with a thickness of 300 nm was formed on a silicon substrate with a thickness of 0.725 mm, and the storage element 3 shown in FIG. 10 was formed thereon.

A Cu film (to be the word line to be described layer) with a film thickness of 100 nm (not shown) was provided between the base layer and the silicon substrate.

The layers other than the insulating layer 16 were formed using a DC magnetron sputtering method. Since the insulating layer was formed of MgO, and it was formed by the RF magnetron sputtering method. After the layers of the storage element 3 were formed, a heat treatment was performed at 300° C. for one hour or at 350° C. for one hour in a magnetic field heating furnace.

Then, the word line part was masked by photolithography, and then selective etching was performed by Ar plasma on the laminated film at a part other than the word line, to form the word line (lower electrode).

In this case, except for the word line part, the etching was performed up to 5 nm of a depth of the substrate.

Thereafter, a mask of a pattern of the storage element 3 was formed by an electronic beam photolithography device, and selective etching was performed on the laminated film, to form the storage element 3. Except for the storage element 3 part, etching was performed up to the immediately above the Cu layer of the word line.

In a storage element for characteristic assessment, since it is necessary to cause sufficient electric current to flow in the storage element to generate a spin torque necessary for the magnetization inversion, it is necessary to suppress the resistance value of the tunnel insulating layer. In the pattern of the storage element 3, the area resistance value (Ωμm²) of the storage element 3 was 20 Ωμm² as an oval shape of the shortest axis of 0.07 μm× the longest axis of 0.07 μm in the oval.

Then, a part other than the storage element 3 part was insulated by sputtering of Al₂O₃ with a thickness of about 100 nm.

Thereafter, a bit line to be the upper electrode and a pad for measurement were formed using photolithography. As described above, the sample of the storage element 3 was produced.

Before measurement, it was configured that magnetic field was applied from the outside the storage element 3 such that it is possible to control values in a plus direction and a minus direction of the inversion electric current to be symmetry.

Voltage applied to the storage element 3 was set up to 1 V in a range in which the insulating layer 16 is not broken.

(Measurement of Magnetoresistance Curve)

Assessment of the magnetoresistance curve of the storage element 3 was performed by measuring the element resistance while applying magnetic field.

(Measurement of Inversion Current Value and Thermal Stability)

The measurement of the inversion current value was performed to assess the writing characteristics of the storage element 3 according to the embodiment.

Electric current with a pulse width of 10 μs to 100 ms is allowed to flow in the storage element 3, and the resistance value of the storage element 3 thereafter was measured.

The amount of electric current flowing in the storage element 3 was changed, and the current value in which the direction of magnetization M17 of the storage layer 17 of the storage element 3 is reversed was acquired. A value obtained by inserting the pulse width dependency of the current value to the outside in the pulse with of 1 ns was the inversion current value.

A slope of the dependency of the pulse width of the inversion current value corresponds to an indicator (Δ) of the thermal stability of the storage element 3 described above. As the inversion current value is not changed by the pulse width (the slope is small), it means that it is strong against disturbance of heat.

To consider a gap between the storage elements 3, about twenty storage elements 3 with the same configuration were produced, the measurement described above was performed, and an average value of the inversion current value and the indicator Δ of the thermal stability was acquired.

In Table 6, the magnetoresistance curve of the sample 6 and the sample 7 at the heat treatment temperature of 350° C. and the assessment of the thermal stability in writing based on electric current were shown. In the sample 6, significant deterioration can be seen in both of the MR ratio and the thermal stability by raising the heat treatment temperature to 350° C. Even when the heat treatment temperature is raised to 350° C. in the sample 7, the deterioration of the MR ratio and the thermal stability are not seen.

In the case of the heat treatment of 300° C., the thermal stability is substantially the same value as that of the case of the heat treatment of 350° C., and it is improved in the sample 6 and the sample 7. This is thought because the magnetization fixed layer 15 is the laminated ferri-pinned structure.

TABLE 6

| | Heat Treatment | | |
|---|---|---|---|
| | Condition | MR ratio [%] | Thermal Stability_Δ |
| Sample 6 | 350° C. 1 Hour | 22 | 37 |
| Sample 7 | | 65 | 56 |

### 6. Modified Example

The embodiments have been described above, but the present disclosure is not limited to the film configuration of the storage element 3 described in the embodiments, and various layer configurations may be employed.

For example, in the embodiment, the compositions of Co—Fe—B of the storage layer 17 and the magnetization fixed layer 15 are the same, but are not limited to the embodiments described above, and the other various configurations may be taken within the scope which does not deviate from the concept of the present disclosure.

In the embodiments, only the single base layer 14, cap material, or the shape of the storage element are described, but is not limited thereto, and the other various configurations may be taken within the scope which does not deviate from the concept of the present disclosure.

The film configuration of the storage element has no problem even in the configuration in which the storage layer 17 is provided above the magnetization fixed layer 15 and the configuration in which it is provided thereunder. In addition, it has no problem even in a so-called dual structure in which the magnetization fixed layer 15 is provided above and under the storage layer 17.

The present disclosure contains subject matter related to that disclosed in Japanese Priority Patent Application JP 2011-021342 filed in the Japan Patent Office on Feb. 3, 2011, the entire contents of which are hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A storage element comprising:
a storage layer that has magnetization perpendicular to a film face, a direction of the magnetization being changed corresponding to information;
a magnetization fixed layer that has magnetization perpendicular to a film face that is a reference of the information stored in the storage layer; and
an insulating layer that is formed of a nonmagnetic body provided between the storage layer and the magnetization fixed layer,
wherein the magnetization fixed layer has a structure in which the nonmagnetic layer is interposed between upper and lower ferromagnetic layers, and the upper and lower ferromagnetic layers have a laminated ferri-pinned structure of magnetically anti-parallel coupling,
wherein the direction of the magnetization of the storage layer is changed by injecting spin-polarized electrons in a lamination direction of a layer structure having the storage layer, the insulating layer, and the magnetization fixed layer, and recording of the information is performed on the storage layer, and
wherein magnitude of effective diamagnetic field received by the storage layer is less than a saturation magnetization amount of the storage layer.

2. The storage element according to claim 1, wherein a plurality of structures are formed in which the nonmagnetic layer is interposed between the upper and lower ferromagnetic layers.

3. The storage element according to claim 2, wherein a ferromagnetic material constituting an interface of the storage layer and the insulating layer is Co—Fe—B.

4. The storage element according to claim 3, wherein a composition of Co—Fe—B is (Coₓ—Fe_{y})_{100-z}—B_{z}
where
0≦Coₓ≦40,
60≦Fe_{y}≦100, and
0<B_{z}≦30.

5. The storage element according to claim 3, wherein a composition of Co—Fe—B is (Coₓ—Fe_{y})_{100-z}—B_{z}
where
0≦Coₓ≦40,
60≦Fe_{y}≦100, and
20<B_{z}≦40.

6. The storage element according to claim 4, wherein a material of the ferromagnetic layer constituting the magnetization fixed layer is Co—Fe—B, and a composition thereof is (Coₓ—Fe_{y})_{100-z}—B_{z}
where
0≦Coₓ≦40,
60≦Fe_{y}≦100, and
0<B_{z}≦30.

7. The storage element according to claim 5, wherein a material of the ferromagnetic layer constituting the magnetization fixed layer is Co—Fe—B, and a composition thereof is (Coₓ—Fe_{y})_{100-z}—B_{z}
where
0≦Coₓ≦40,
60≦Fe_{y}≦100, and
20<B_{z}≦40.

8. The storage element according to claim 6, wherein the nonmagnetic layer constituting the structure interposed therebetween on the insulating layer side among the plurality of structures in which the nonmagnetic layer is interposed between the upper and lower ferromagnetic layers is Ta.

9. The storage element according to claim 7, wherein the nonmagnetic layer constituting the structure interposed therebetween on the insulating layer side among the plurality of structures in which the nonmagnetic layer is interposed between the upper and lower ferromagnetic layers is Ta.

10. A memory device comprising:
a storage element that stores information by a magnetization state of a magnetic body; and
two kinds of lines that intersect with each other,
wherein the storage element includes a storage layer that has magnetization perpendicular to a film face, a direction of the magnetization being changed corresponding to information, a magnetization fixed layer that has magnetization perpendicular to a film face that is a reference of the information stored in the storage layer, and an insulating layer that is formed of a nonmagnetic body provided between the storage layer and the magnetization fixed layer, the magnetization fixed layer has a structure in which the nonmagnetic layer is interposed between upper and lower ferromagnetic layers, and the upper and lower ferromagnetic layers have a laminated ferri-pinned structure of magnetically anti-parallel coupling, the direction of the magnetization of the storage layer is changed by injecting spin-polarized electrons in a lamination direction of a layer structure having the storage layer, the insulating layer, and the magnetization fixed layer, and recording of the information is performed on the storage layer, and magnitude of effective diamagnetic field received by the storage layer is less than a saturation magnetization amount of the storage layer,
wherein the storage element is provided between the two kinds of lines, and
wherein electric current in the lamination direction flows in the storage element through the two kinds of lines, and the spin-polarized electrons are injected.
